(19) United States
(12) Patent Application Publication
(10) Pub. No.: US 2025/0379135 A1
(43) Pub. Date: Dec. 11, 2025

(54) PACKAGE COMPRISING AN INTEGRATED DEVICE AND AN OFFSET MEMORY DEVICE

(71) Applicant: QUALCOMM Incorporated, San Diego, CA (US)

(72) Inventors: Manuel ALDRETE, Encinitas, CA (US); Rajneesh KUMAR, San Diego, CA (US); Aniket PATIL, San Diego, CA (US); Ryan LANE, San Diego, CA (US); Piyush GUPTA, San Diego, CA (US)

(21) Appl. No.: 18/736,274

(22) Filed: Jun. 6, 2024

(51) Int. Cl. H01L 23/498; H01L 23/00; H01L 23/367; H01L 25/065

(52) U.S. Cl. CPC H01L 23/49838; H01L 23/3672; H01L 23/49816; H01L 24/08; H01L 24/16; H01L 25/0655; H01L 2224/08146; H01L 2224/08225; H01L 2224/16146; H01L 2224/16227; H01L 2924/0665; H01L 2924/1434; H01L 2924/15311; H01L 2924/182; H01L 2924/351

(57) ABSTRACT

A package comprising a metallization portion; an integrated device coupled to the metallization portion; a substrate; a plurality of wire bonds coupled to the substrate and the metallization portion; and an encapsulation layer coupled to the metallization portion, wherein the encapsulation layer at least partially encapsulates the integrated device, the plurality of wire bonds and the substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with substrates and integrated devices.

One example provides a package comprising a metallization portion; an integrated device coupled to the metallization portion; a substrate; a plurality of wire bonds coupled to the substrate and the metallization portion; and an encapsulation layer coupled to the metallization portion, wherein the encapsulation layer at least partially encapsulates the integrated device, the plurality of wire bonds and the substrate.

Another example provides a package comprising a metallization portion; a first integrated device coupled to the metallization portion; a second integrated device; a heat sink coupled to the first integrated device through a thermal interface material (TIM) and/or an adhesive; a plurality of package interconnects coupled to the second integrated device and the metallization portion; and an encapsulation layer coupled to the metallization portion, wherein the encapsulation layer at least partially encapsulates the first integrated device, the second integrated device, the plurality of package interconnects and the heat sink.

Another example provides a package comprising a metallization portion; an integrated device coupled to the metallization portion; a substrate; a plurality of post interconnects coupled to the substrate and the metallization portion; and an encapsulation layer coupled to the metallization portion, wherein the encapsulation layer at least partially encapsulates the integrated device, the plurality of post interconnects and the substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, a metallization portion, a substrate and a plurality of wire bonds.

FIG. 2 illustrates an exemplary cross sectional profile view of a package that includes a substrate, a metallization portion, a substrate and a plurality of wire bonds.

FIG. 3 illustrates an exemplary cross sectional profile view of a package that includes a substrate, a metallization portion, a substrate and a plurality of wire bonds.

FIG. 4 illustrates an exemplary cross sectional profile view of a package that includes a substrate, a metallization portion, a substrate, a heat sink and a plurality of wire bonds.

FIG. 5 illustrates an exemplary cross sectional profile view of a package that includes a substrate, a metallization portion, a heat sink and a plurality of post interconnects.

FIG. 6 illustrates an exemplary cross sectional profile view of a package that includes a substrate, a metallization portion, a substrate and a plurality of post interconnects.

FIG. 7 illustrates an exemplary cross sectional profile view of a package that includes a substrate, a metallization portion, a substrate and a plurality of post interconnects.

FIG. 8 illustrates an exemplary cross sectional profile view of a package that includes a substrate, a metallization portion, a substrate, a heat sink and a plurality of post interconnects.

FIG. 9 illustrates an exemplary cross sectional profile view of a package that includes a substrate, a metallization portion, a heat sink and a plurality of post interconnects.

FIGS. 10A-10C illustrate an exemplary sequence for fabricating a package that includes an integrated device and a plurality of wire bonds.

FIGS. 11A-11C illustrate an exemplary sequence for fabricating a package that includes an integrated device and a plurality of wire bonds.

FIGS. 12A-12C illustrate an exemplary sequence for fabricating a package that includes an integrated device and a plurality of wire bonds.

FIGS. 13A-13C illustrate an exemplary sequence for fabricating a package that includes an integrated device and a plurality of wire bonds.

FIG. 14 illustrates an exemplary flow chart of a method for fabricating a package that includes an integrated device and a plurality of wire bonds.

FIGS. 15A-15C illustrate an exemplary sequence for fabricating a package that includes an integrated device and a plurality of post interconnects.

FIGS. 16A-16C illustrate an exemplary sequence for fabricating a package that includes an integrated device and a plurality of post interconnects.

FIGS. 17A-17C illustrate an exemplary sequence for fabricating a package that includes an integrated device and a plurality of post interconnects.

FIGS. 18A-18C illustrate an exemplary sequence for fabricating a package that includes an integrated device and a plurality of post interconnects.

FIG. 19 illustrates an exemplary flow chart of a method for fabricating a package that includes an integrated device and a plurality of post interconnects.

FIGS. 20A-20B illustrate an exemplary sequence for fabricating a metallization portion.

FIG. 21 illustrates an exemplary flow chart of a method for fabricating a metallization portion.

FIG. 22 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a metallization portion; an integrated device coupled to the metallization portion; a substrate; a plurality of wire bonds coupled to the substrate and the metallization portion; and an encapsulation layer coupled to the metallization portion, wherein the encapsulation layer at least partially encapsulates the integrated device, the plurality of wire bonds and the substrate.

### Exemplary Package Comprising an Integrated Device and Wire Bonds

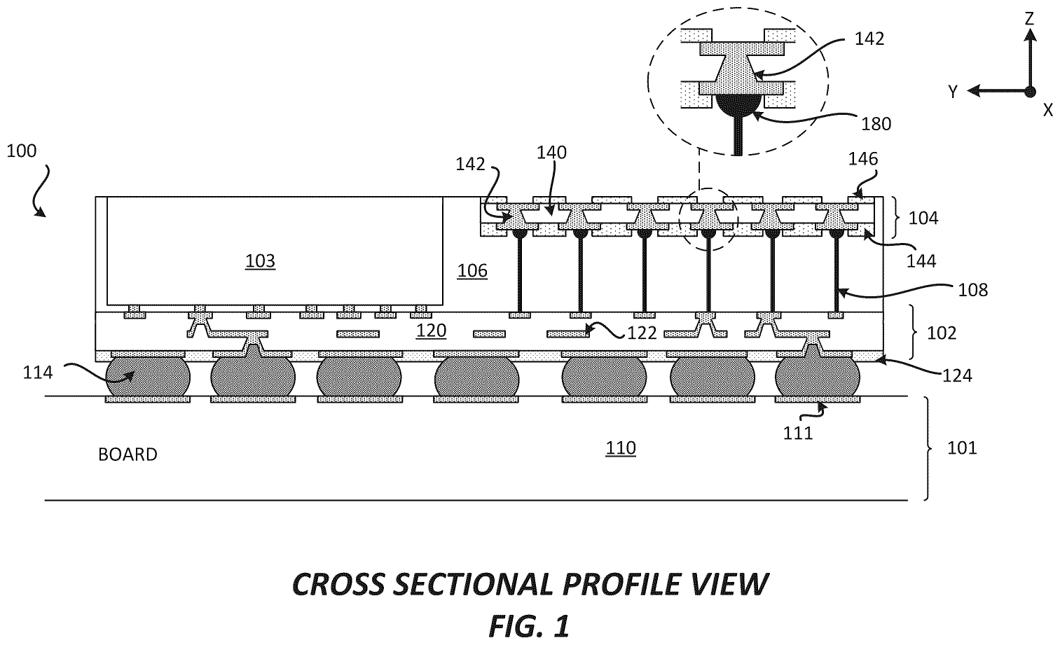

FIG. 1 illustrates a cross sectional profile view of a package 100 that includes a plurality of wire bonds. The package 100 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 100 includes a metallization portion 102, an integrated device 103, a substrate 104, a plurality of wire bonds 108 and an encapsulation layer 106. The metallization portion 102 includes at least one dielectric layer 120, a plurality of metallization interconnects 122 and a solder resist layer 124. The substrate 104 may be an interposer (e.g., package interposer). The substrate 104 may include a dielectric layer 140 (e.g., interposer dielectric layer), a plurality of interconnects 142 (e.g., interposer interconnects), a solder resist layer 144 and a solder resist layer 146. In some implementations, the dielectric layer 140 (e.g., interposer dielectric layer) may include silicon, glass or an organic dielectric layer. The substrate 104 has a lateral size that is less than the lateral size of the metallization portion 102. In some implementations, the dielectric layer 140 may include prepreg and/or polyimide.

The encapsulation layer 106 is coupled to the metallization portion 102, the substrate 104 and the metallization portion 102. The encapsulation layer 106 may at least partially encapsulate the integrated device 103, the plurality of wire bonds 108 and the substrate 104. Thus, the integrated device 103, the plurality of wire bonds 108 and/or the substrate 104 may be located at least partially in the encapsulation layer 106. The encapsulation layer 106 may include a mold, a resin, an epoxy and/or a filler. The encapsulation layer 106 may be located between the metallization portion 102 and the substrate 104. The substrate 104 and the plurality of wire bonds 108 may be located laterally to the integrated device 103. The encapsulation layer 106 may be located vertically between the metallization portion 102 and the substrate 104.

The plurality of wire bonds 108 are coupled to the substrate 104 and the metallization portion 102. The plurality of wire bonds 108 may be coupled to and touch (i) the plurality of metallization interconnects 122 of the metallization portion 102 and (ii) the plurality of interconnects 142 of the substrate 104. The plurality of wire bonds 108 may include a plurality of ball bonds 180. The plurality of ball bonds 180 may be considered part of the plurality of wire bonds 108. The plurality of ball bonds 180 of the plurality of wire bonds 108, may be coupled to and touch the plurality of interconnects 142 of the substrate 104.

The integrated device 103 may be coupled to and touch the metallization portion 102. The integrated device 103 may be coupled to the plurality of metallization interconnects 122 of the metallization portion 102. The integrated device 103 may include a plurality of pad interconnects and/or a plurality of pillar interconnects. The plurality of pad interconnects and/or a plurality of pillar interconnects of the integrated device 103 may be coupled to and touch the plurality of metallization interconnects 122 of the metallization portion 102. The metallization portion 102 may include a redistribution portion. The plurality of metallization interconnects 122 may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

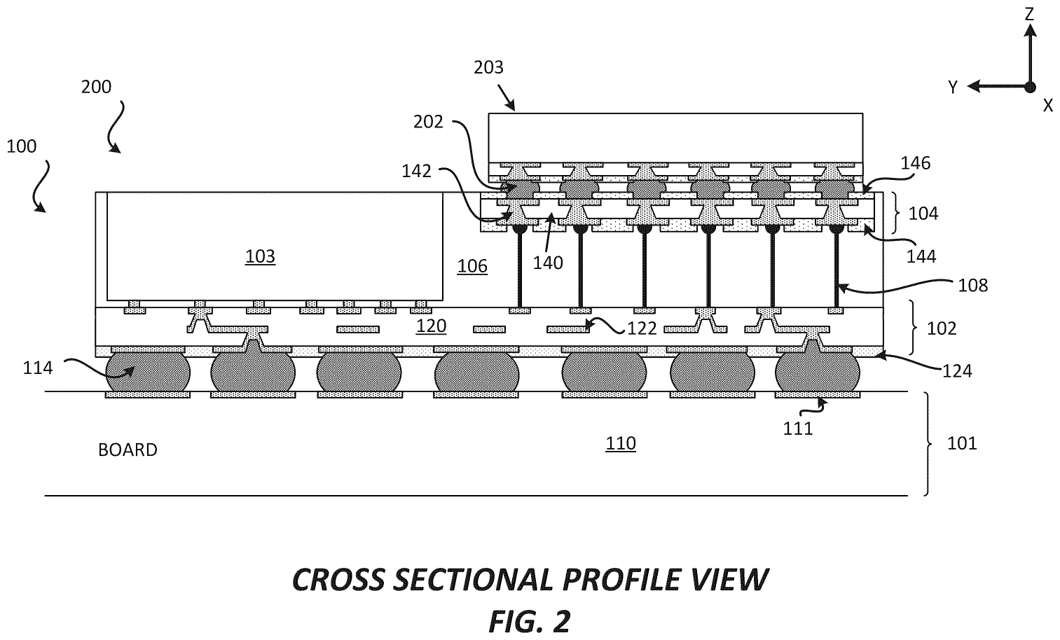

FIG. 2 illustrates a package 200 that includes the package 100 and a package 203. The package 200 may be a package on package (POP). The package 203 is coupled to the package 100 through a plurality of solder interconnects 202. The package 203 may include a memory package (e.g., memory chip). The package 203 may be an integrated device package. The package 203 may include at least one integrated device, a metallization portion, a substrate, an interposer, and/or an encapsulation layer. The package 203 may be coupled to the substrate 104 of the package 100 through the plurality of solder interconnects 202. The plurality of solder interconnects 202 may be coupled to the plurality of interconnects 142 of the substrate 104 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 104, another integrated device may be coupled to the substrate 104. The package 203 and/or the substrate 104 may be offset (e.g., horizontally offset) from the integrated device 103. The package 203 may or may not vertically overlap with a portion of the integrated device 103. The package 203 vertically overlaps at least partially with the substrate 104.

An electrical path between the integrated device 103 and the package 203 may include (i) the metallization portion 102, (ii) the plurality of wire bonds 108, (iii) the substrate 104, and/or (iv) the plurality of solder interconnects 202. For example, an electrical path between the integrated device 103 and the package 203 may include (i) at least one metallization interconnect from the plurality of metallization interconnects 122, (ii) at least one wire bond from the plurality of wire bonds 108, (iii) at least one interconnect from the plurality of interconnects 142 and/or (iv) at least one solder interconnect from the plurality of solder interconnects 202.

The configuration of the package 200 provides a package with improved heat dissipation and/or thermal performance, which helps improve the performance (e.g., thermal performance) of the package 100 and/or the package 200. This is possible because the substrate 104 and/or the package 203 is/are offset (e.g., horizontally offset) from the integrated device 103 and does not cover the back side of the integrated device 103. In some implementations, the use of the plurality of wire bonds 108 helps provide high aspect ratio interconnects that can extend through the encapsulation layer 106, and may be useful for integrated device 103 with high thicknesses.

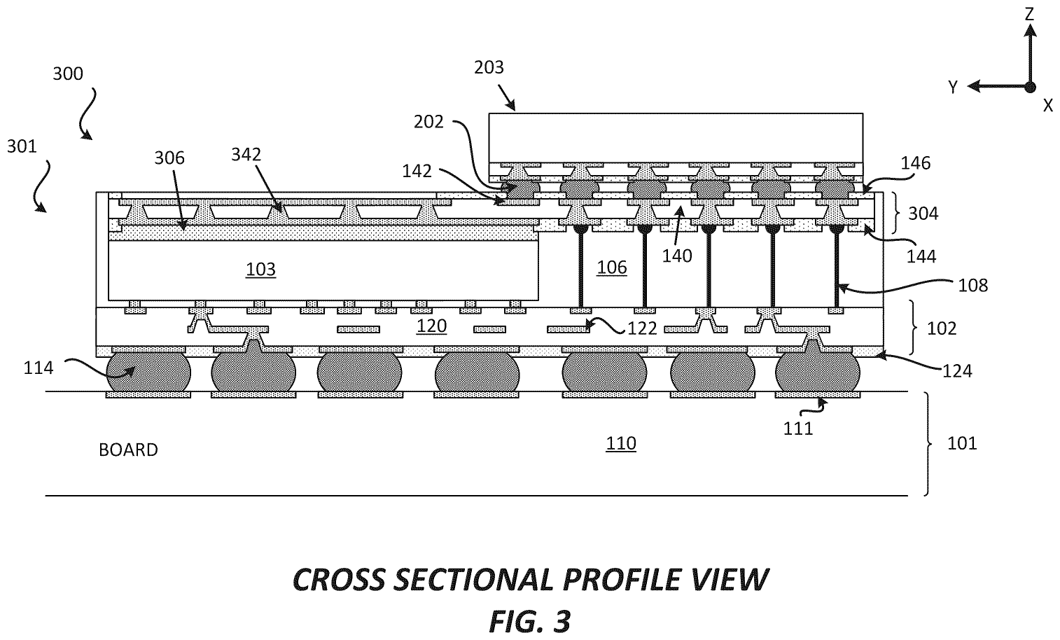

FIG. 3 illustrates a cross sectional profile view of a package 300 that includes a package 301 and the package 203. The package 300 may be a package on package (POP). The package 203 is coupled to the package 301 through a plurality of solder interconnects 202. The package 203 may include a memory package (e.g., memory chip). The package 203 may include at least one integrated device, a metallization portion, a substrate, an interposer, and/or an encapsulation layer. The package 203 is coupled to a substrate 304 through the plurality of solder interconnects 202. The plurality of solder interconnects 202 may be coupled to the plurality of interconnects 142 of the substrate 304 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 304, another integrated device may be coupled to the substrate 304. The package 203 may be offset (e.g., horizontally offset) from the integrated device 103. The package 203 may or may not vertically overlap with a portion of the integrated device 103.

The package 301 is coupled to a board 101 through a plurality of solder interconnects 114. The package 301 includes a metallization portion 102, an integrated device 103, a substrate 304, a plurality of wire bonds 108, a thermal interface material (TIM) 306 and an encapsulation layer 106. The metallization portion 102 includes at least one dielectric layer 120, a plurality of metallization interconnects 122 and a solder resist layer 124. The substrate 304 may be an interposer (e.g., package interposer). The substrate 304 may include a dielectric layer 140 (e.g., interposer dielectric layer), a plurality of interconnects 142 (e.g., interposer interconnects), a plurality of interconnects 342, a solder resist layer 144 and a solder resist layer 146. The plurality of interconnects 342 may be configured as a heat sink. The plurality of interconnects 342 may be a plurality of heat sink interconnects. The plurality of interconnects 342 may vertically overlap with the integrated device 103. The plurality of interconnects 342 may or may not touch the plurality of interconnects 142. In some implementations, one or more of the interconnects from the plurality of interconnects 342 may be free of any electrical connection with circuits and/or electrical components of the package 300, the package 301, the package 203 and/or the integrated device 103. In some implementations, the dielectric layer 140 (e.g., interposer dielectric layer) may include silicon, glass or an organic dielectric layer. In some implementations, the dielectric layer 140 may include prepreg and/or polyimide.

The encapsulation layer 106 is coupled to the metallization portion 102, the substrate 304 and the metallization portion 102. The encapsulation layer 106 may at least partially encapsulate the integrated device 103, the plurality of wire bonds 108 and the substrate 104. Thus, the integrated device 103, the plurality of wire bonds 108 and/or the substrate 304 may be located at least partially in the encapsulation layer 106. The encapsulation layer 106 may include a mold, a resin, an epoxy and/or a filler. The encapsulation layer 106 may be located between the metallization portion 102 and the substrate 304. The plurality of wire bonds 108 may be located laterally to the integrated device 103.

The plurality of wire bonds 108 are coupled to the substrate 304 and the metallization portion 102. The plurality of wire bonds 108 may be coupled to and touch (i) the plurality of metallization interconnects 122 of the metallization portion 102 and (ii) the plurality of interconnects 142 of the substrate 304. The plurality of wire bonds 108 may include a plurality of ball bonds 180. The plurality of ball bonds 180 may be considered part of the plurality of wire bonds 108. The plurality of ball bonds 180 may be coupled to and touch the plurality of interconnects 142 of the substrate 304.

The integrated device 103 is coupled to and touch the metallization portion 102. The integrated device 103 is coupled to the plurality of metallization interconnects 122 of the metallization portion 102. The integrated device 103 is coupled to the substrate 304 through a thermal interface material (TIM) 306. For example, a back side of the integrated device 103 may be coupled to the plurality of interconnects 342 of the substrate 304 through the thermal interface material (TIM) 306. As mentioned above, a part of the substrate 304 may be configured to operate as a heat sink. The back side of the integrated device 103 may be the side that includes a die substrate (e.g., silicon substrate). A portion of the integrated device 103 may or may not vertically overlap with a portion of the package 203.

An electrical path between the integrated device 103 and the package 203 may include (i) the metallization portion 102, (ii) the plurality of wire bonds 108, (iii) the substrate 304, and/or (iv) the plurality of solder interconnects 202. For example, an electrical path between the integrated device 103 and the package 203 may include (i) at least one metallization interconnect from the plurality of metallization interconnects 122, (ii) at least one wire bond from the plurality of wire bonds 108, (iii) at least one interconnect from the plurality of interconnects 142 and/or (iv) at least one solder interconnect from the plurality of solder interconnects 202.

The configuration of the package 300 provides a package with improved heat dissipation and/or thermal performance, which helps improve the performance of the package 301 and/or the package 300. This is possible because the substrate 304 and/or the package 203 is offset from the integrated device 103, and a part of the substrate 304 is used as heat sink. In some implementations, the use of the plurality of wire bonds 108 helps provide high aspect ratio interconnects that can extend through the encapsulation layer 106, and may be useful for integrated device 103 with high thicknesses.

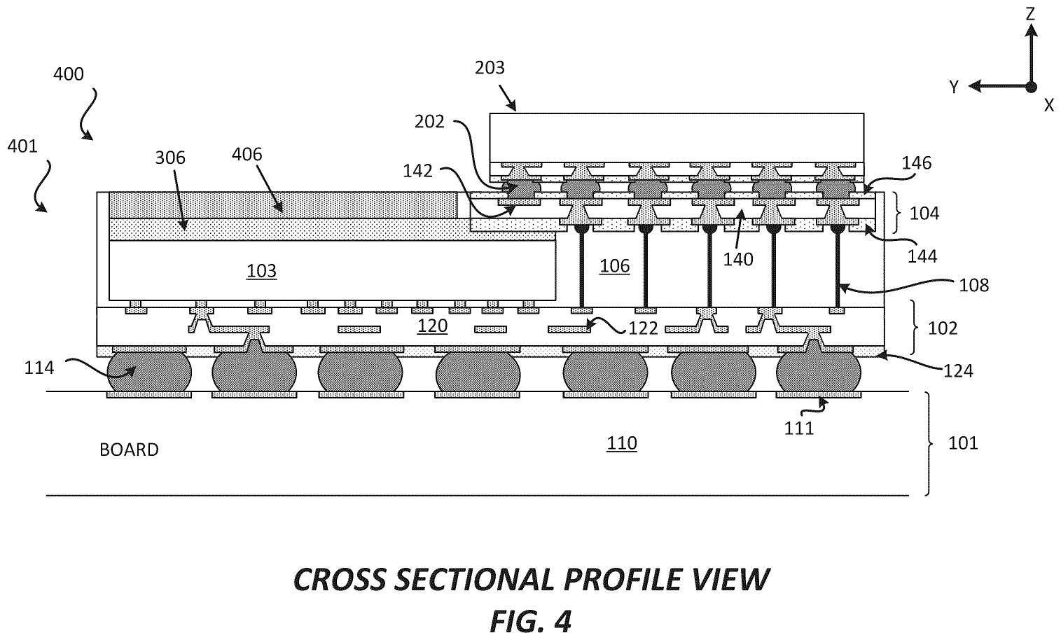

FIG. 4 illustrates a cross sectional profile view of a package 400 that includes a package 401 and the package 203. The package 400 may be a package on package (POP). The package 203 is coupled to the package 401 through a plurality of solder interconnects 202. The package 203 may include a memory package (e.g., memory chip). The package 203 may include at least one integrated device, a metallization portion, a substrate, an interposer, and/or an encapsulation layer. The package 203 is coupled to a substrate 104 through the plurality of solder interconnects 202. The plurality of solder interconnects 202 may be coupled to the plurality of interconnects 142 of the substrate 104 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 104, another integrated device may be coupled to the substrate 104. The package 203 and/or the substrate 104 may be offset from the integrated device 103.

The package 401 is coupled to a board 101 through a plurality of solder interconnects 114. The package 401 includes a metallization portion 102, an integrated device 103, a substrate 104, a plurality of wire bonds 108, an encapsulation layer 106, a thermal interface material (TIM) 306 and a heat sink 406. The metallization portion 102 includes at least one dielectric layer 120, a plurality of metallization interconnects 122 and a solder resist layer 124. The substrate 104 may be an interposer (e.g., package interposer). The substrate 104 may include a dielectric layer 140 (e.g., interposer dielectric layer), a plurality of interconnects 142 (e.g., interposer interconnects), a solder resist layer 144 and a solder resist layer 146. In some implementations, the dielectric layer 140 (e.g., interposer dielectric layer) may include silicon, glass or an organic dielectric layer. The substrate 104 has a lateral size that is less than the lateral size of the metallization portion 102. In some implementations, the dielectric layer 140 may include prepreg and/or polyimide.

The encapsulation layer 106 is coupled to the metallization portion 102, the substrate 104 and the metallization portion 102. The encapsulation layer 106 may at least partially encapsulate the integrated device 103, the plurality of wire bonds 108, the substrate 104 and the heat sink 406. Thus, the integrated device 103, the plurality of wire bonds 108, the substrate 104, the thermal interface material (TIM) 306 and/or the heat sink 406 may be located at least partially in the encapsulation layer 106. The encapsulation layer 106 may include a mold, a resin, an epoxy and/or a filler. The encapsulation layer 106 may be located between the metallization portion 102 and the substrate 104. The substrate 104 and the plurality of wire bonds 108 may be located laterally to the integrated device 103. The integrated device 103 may vertically overlap (i) with at least a portion of the heat sink 406, (ii) with at least a portion of the substrate 104, and/or (iii) with at least a portion of the package 203.

The plurality of wire bonds 108 are coupled to the substrate 104 and the metallization portion 102. The plurality of wire bonds 108 may be coupled to and touch (i) the plurality of metallization interconnects 122 of the metallization portion 102 and (ii) the plurality of interconnects 142 of the substrate 104. The plurality of wire bonds 108 may include a plurality of ball bonds 180. The plurality of ball bonds 180 may be considered part of the plurality of wire bonds 108. The plurality of ball bonds 180 may be coupled to and touch the plurality of interconnects 142 of the substrate 104.

The integrated device 103 is coupled to and touch the metallization portion 102. The integrated device 103 is coupled to the plurality of metallization interconnects 122 of the metallization portion 102. The integrated device 103 may be coupled to the substrate 104 through a thermal interface material (TIM) 306. The integrated device 103 may be coupled to the heat sink 406 through a thermal interface material (TIM) 306. For example, a back side of the integrated device 103 is coupled to the heat sink 406 through the thermal interface material (TIM) 306. The back side of the integrated device 103 may be the side that includes a die substrate (e.g., silicon substrate). A portion of the integrated device 103 may vertically overlap with a portion of the package 203 and/or a portion of the substrate 104. In some implementations, the integrated device 103 may not vertically overlap with the package 203. In some implementations, the integrated device 103 may not vertically overlap with the substrate 104. The heat sink 406 may be located laterally to the substrate 104.

An electrical path between the integrated device 103 and the package 203 may include (i) the metallization portion 102, (ii) the plurality of wire bonds 108, (iii) the substrate 104, and/or (iv) the plurality of solder interconnects 202. For example, an electrical path between the integrated device 103 and the package 203 may include (i) at least one metallization interconnect from the plurality of metallization interconnects 122, (ii) at least one wire bond from the plurality of wire bonds 108, (iii) at least one interconnect from the plurality of interconnects 142 and/or (iv) at least one solder interconnect from the plurality of solder interconnects 202.

The configuration of the package 400 provides a package with improved heat dissipation and/or thermal performance, which helps improve the performance of the package 401 and/or the package 400. This is possible because the substrate 104 and/or the package 203 is offset from the integrated device 103, and a heat sink 406 is provided to help dissipate heat away from the integrated device 103. In some implementations, the use of the plurality of wire bonds 108 helps provide high aspect ratio interconnects that can extend through the encapsulation layer 106, and may be useful for integrated device 103 with high thicknesses.

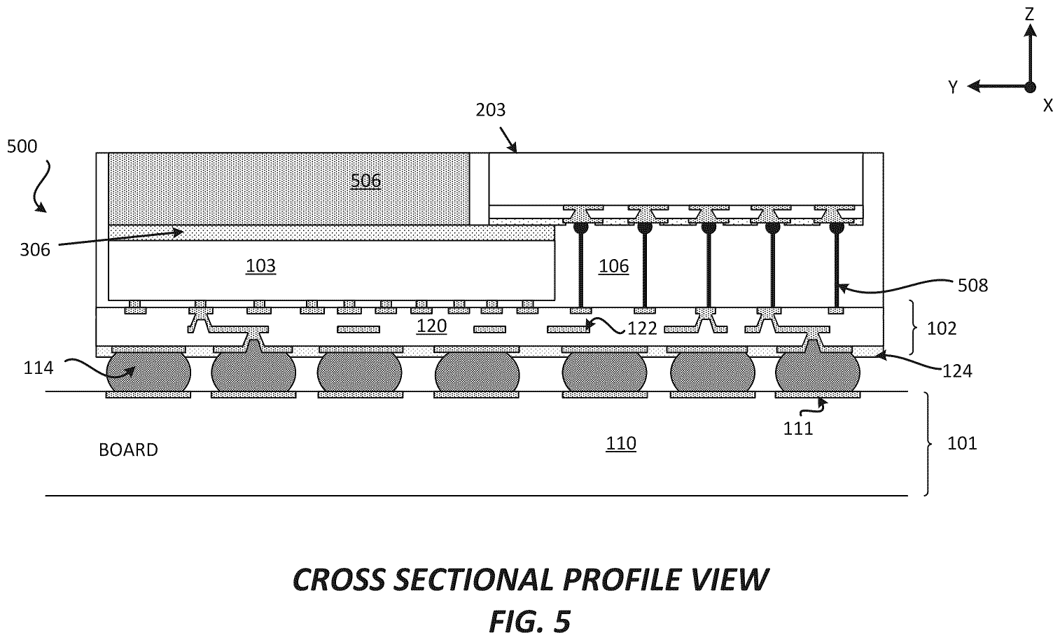

FIG. 5 illustrates a cross sectional profile view of a package 500 that includes an integrated device and a plurality of wire bonds. The package 500 is coupled to a board 101 through a plurality of solder interconnects 114. The package 500 includes a metallization portion 102, an integrated device 103, a plurality of wire bonds 508, a package 203, an encapsulation layer 106, a thermal interface material (TIM) 306 and a heat sink 506. The metallization portion 102 includes at least one dielectric layer 120, a plurality of metallization interconnects 122 and a solder resist layer 124. The package 203 may include at least one integrated device, a metallization portion, a substrate, an interposer, and/or an encapsulation layer. The package 203 may include a memory package (e.g., memory chip).

The encapsulation layer 106 is coupled to the metallization portion 102, the substrate 104 and the metallization portion 102. The encapsulation layer 106 may at least partially encapsulate the integrated device 103, the plurality of wire bonds 508, the thermal interface material (TIM) 306 and the heat sink 506. Thus, the integrated device 103, the plurality of wire bonds 508, and/or the heat sink 406 may be located at least partially in the encapsulation layer 106. The encapsulation layer 106 may include a mold, a resin, an epoxy and/or a filler. The encapsulation layer 106 may be located between the metallization portion 102 and the package 203. The heat sink 506 may be located laterally to the package 203.

The plurality of wire bonds 508 are coupled to the package 203 and the metallization portion 102. The plurality of wire bonds 508 may be coupled to and touch (i) the plurality of metallization interconnects 122 of the metallization portion 102 and (ii) interconnects of the package 203. The plurality of wire bonds 508 may include a plurality of ball bonds 180. The plurality of ball bonds 180 may be considered part of the plurality of wire bonds 508. The plurality of ball bonds 180 may be coupled to and touch the plurality of interconnects of the package 203. In some implementations, interconnects of the package 203 may include metallization interconnects, substrate interconnects, and/or pad interconnects of the package 203.

The integrated device 103 is coupled to and touch the metallization portion 102. The integrated device 103 is coupled to the plurality of metallization interconnects 122 of the metallization portion 102. The integrated device 103 may be coupled to the package 203 through a thermal interface material (TIM) 306. The integrated device 103 may be coupled to the heat sink 506 through a thermal interface material (TIM) 306. For example, a back side of the integrated device 103 is coupled to the heat sink 506 through the thermal interface material (TIM) 306. The back side of the integrated device 103 may be coupled to the package 203 through the thermal interface material (TIM) 306. The back side of the integrated device 103 may be the side that includes a die substrate (e.g., silicon substrate). A portion of the integrated device 103 may vertically overlap with a portion of the package 203. In some implementations, the integrated device 103 may not vertically overlap with the package 203. The heat sink 506 may be located laterally to the package 203. The heat sink 506 may vertically overlap with the integrated device 103.

An electrical path between the integrated device 103 and the package 203 may include (i) the metallization portion 102 and (ii) the plurality of wire bonds 508. For example, an electrical path between the integrated device 103 and the package 203 may include (i) at least one metallization interconnect from the plurality of metallization interconnects 122 and (ii) at least one wire bond from the plurality of wire bonds 508.

The configuration of the package 500 provides a package with improved heat dissipation and/or thermal performance, which helps improve the performance of the package 500. In comparison to the package 200, the package 300 and/or the package 400, the package 500 bypasses the use of a substrate (e.g., 104, 304), which can help reduce the overall size of the package. In some implementations, the use of the plurality of wire bonds 508 helps provide high aspect ratio interconnects that can extend through the encapsulation layer 106, and may be useful for integrated device 103 with high thicknesses.

In some implementations, the plurality of wire bonds (e.g., 108, 508) may have a height in a range of about 200-700 micrometers. In some implementations, the plurality of wire bonds (e.g., 108, 508) may have a width in a range of about 20-75 micrometers. In some implementations, the plurality of wire bonds (e.g., 108, 508) may have a spacing in a range of about 50-200 micrometers. In some implementations, a wire bond may have an aspect ratio (e.g., height to width ratio) that is at least 2. In some implementations, a wire bond may have an aspect ratio (e.g., height to width ratio) that is at least 5. In some implementations, a wire bond may have an aspect ratio (e.g., height to width ratio) that is at least 10. However, the plurality of wire bonds (e.g., 108, 508) may have different dimensions, including dimensions that are greater or less than the dimensions listed above. Thus, the above dimensions for the plurality of wire bonds (e.g., 108, 508) are merely exemplary. However, in some implementations, the above dimensions may provide an optimal range in values to minimize the size of the package while still providing enough interconnects in the package.

### Exemplary Package Comprising an Integrated Device and Post Interconnects

In some implementations, instead of a plurality of wire bonds, a plurality of post interconnects may be used and located in the package. A post interconnect is different from a wire bond. For example, a wire bond includes a ball bond. In some implementations, a post interconnect may be an interconnect that has a height to width ratio of at least 2. That is, a post interconnect may be an interconnect whose height is at least 2 times greater than its width. In some implementations, a post interconnect may be an interconnect that has a height to width ratio of at least 3. In some implementations, a post interconnect may be an interconnect that has a height to width ratio of at least 4.

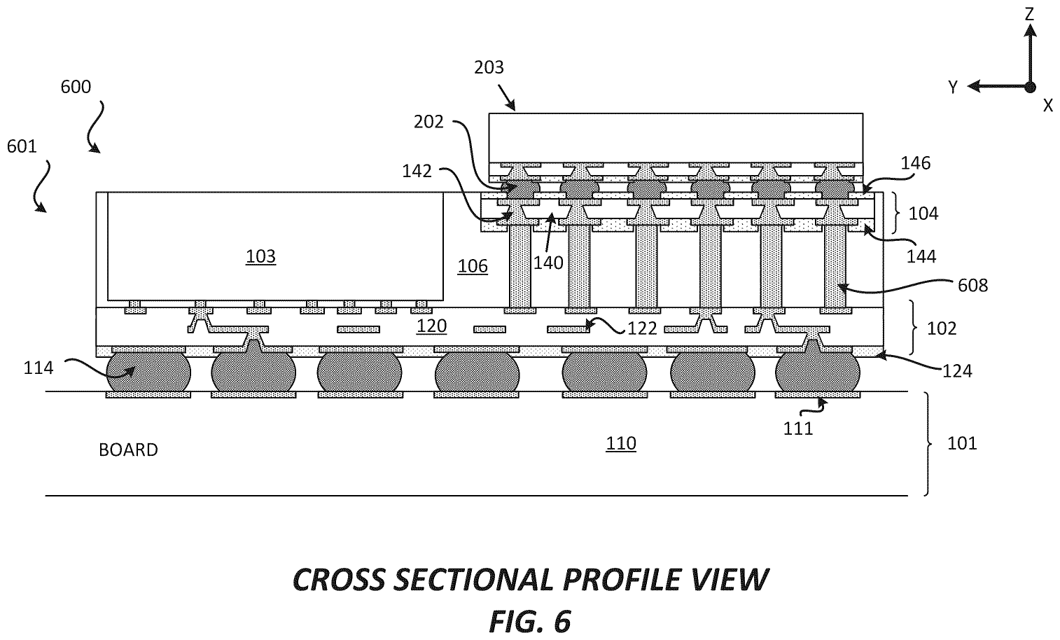

FIG. 6 illustrates a package 600 that includes a package 601 and a package 203. The package 600 may be a package on package (POP). The package 601 is coupled to a board 101 through a plurality of solder interconnects 114. The board 101 includes at least one board dielectric layer 110 and a plurality of board interconnects 112. The board 101 may include a printed circuit board (PCB). In some implementations, the package 601 may be coupled to a substrate instead of the board 101.

The package 601 includes a metallization portion 102, an integrated device 103, a substrate 104, a plurality of post interconnects 608 and an encapsulation layer 106. The metallization portion 102 includes at least one dielectric layer 120, a plurality of metallization interconnects 122 and a solder resist layer 124. The substrate 104 may be an interposer (e.g., package interposer). The substrate 104 may include a dielectric layer 140 (e.g., interposer dielectric layer), a plurality of interconnects 142 (e.g., interposer interconnects), a solder resist layer 144 and a solder resist layer 146. In some implementations, the dielectric layer 140 (e.g., interposer dielectric layer) may include silicon, glass or an organic dielectric layer. The substrate 104 has a lateral size that is less than the lateral size of the metallization portion 102. In some implementations, the dielectric layer 140 may include prepreg and/or polyimide.

The encapsulation layer 106 is coupled to the metallization portion 102, the substrate 104 and the metallization portion 102. The encapsulation layer 106 may at least partially encapsulate the integrated device 103, the plurality of post interconnects 608 and the substrate 104. Thus, the integrated device 103, the plurality of post interconnects 608 and/or the substrate 104 may be located at least partially in the encapsulation layer 106. The encapsulation layer 106 may include a mold, a resin, an epoxy and/or a filler. The encapsulation layer 106 may be located between the metallization portion 102 and the substrate 104. The substrate 104 and the plurality of post interconnects 608 may be located laterally to the integrated device 103. The encapsulation layer 106 may be located vertically between the metallization portion 102 and the substrate 104.

The plurality of post interconnects 608 are coupled to the substrate 104 and the metallization portion 102. The plurality of post interconnects 608 may be coupled to and touch (i) the plurality of metallization interconnects 122 of the metallization portion 102 and (ii) the plurality of interconnects 142 of the substrate 104. The plurality of post interconnects 608 may be a plurality of through mold post interconnects.

The integrated device 103 is coupled to and touch the metallization portion 102. The integrated device 103 may be coupled to the plurality of metallization interconnects 122 of the metallization portion 102. The metallization portion 102 may include a redistribution portion. The plurality of metallization interconnects 122 may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

The package 203 is coupled to the package 601 through a plurality of solder interconnects 202. The package 203 may include a memory package (e.g., memory chip). The package 203 may be an integrated device package. The package 203 may include at least one integrated device, a metallization portion, a substrate, an interposer, and/or an encapsulation layer. The package 203 is coupled to the substrate 104 through the plurality of solder interconnects 202. The plurality of solder interconnects 202 may be coupled to the plurality of interconnects 142 of the substrate 104 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 104, another integrated device may be coupled to the substrate 104. The package 203 and/or the substrate 104 may be offset (e.g., horizontally offset) from the integrated device 103. The package 203 may or may not vertically overlap with a portion of the integrated device 103.

An electrical path between the integrated device 103 and the package 203 may include (i) the metallization portion 102, (ii) the plurality of post interconnects 608, (iii) the substrate 104, and/or (iv) the plurality of solder interconnects 202. For example, an electrical path between the integrated device 103 and the package 203 may include (i) at least one metallization interconnect from the plurality of metallization interconnects 122, (ii) at least one post interconnect from the plurality of post interconnects 608, (iii) at least one interconnect from the plurality of interconnects 142 and/or (iv) at least one solder interconnect from the plurality of solder interconnects 202.

The configuration of the package 600 provides a package with improved heat dissipation and/or thermal performance, which helps improve the performance of the package 601 and/or the package 600. This is possible because the substrate 104 and/or the package 203 is offset from the integrated device 103 and does not cover the back side of the integrated device 103.

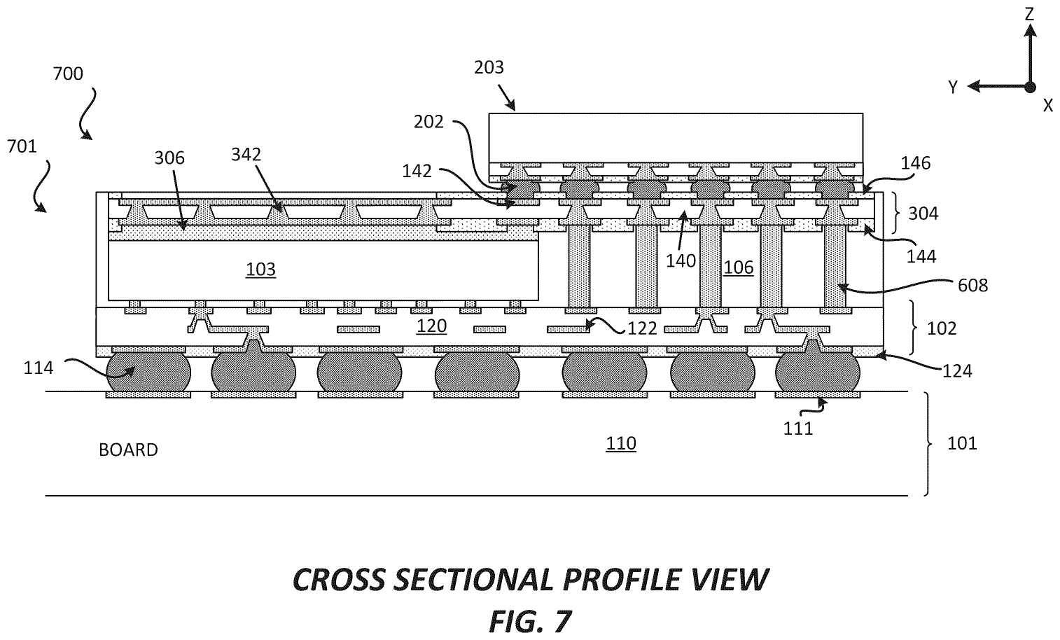

FIG. 7 illustrates a cross sectional profile view of a package 700 that includes a package 701 and the package 203. The package 700 may be a package on package (POP). The package 203 is coupled to the package 701 through a plurality of solder interconnects 202. The package 203 may include a memory package (e.g., memory chip). The package 203 may include at least one integrated device, a metallization portion, a substrate, an interposer, and/or an encapsulation layer. The package 203 is coupled to a substrate 304 through the plurality of solder interconnects 202. The plurality of solder interconnects 202 may be coupled to the plurality of interconnects 142 of the substrate 304 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 304, another integrated device may be coupled to the substrate 304. The package 203 may be offset (e.g., horizontally offset) from the integrated device 103. The package 203 may or may not vertically overlap with a portion of the integrated device 103.

The package 701 is coupled to a board 101 through a plurality of solder interconnects 114. The package 701 includes a metallization portion 102, an integrated device 103, a substrate 304, a plurality of post interconnects 608, a thermal interface material (TIM) 306 and an encapsulation layer 106. The metallization portion 102 includes at least one dielectric layer 120, a plurality of metallization interconnects 122 and a solder resist layer 124. The substrate 304 may be an interposer (e.g., package interposer). The substrate 304 may include a dielectric layer 140 (e.g., interposer dielectric layer), a plurality of interconnects 142 (e.g., interposer interconnects), a plurality of interconnects 342, a solder resist layer 144 and a solder resist layer 146. The plurality of interconnects 342 may be configured as a heat sink. The plurality of interconnects 342 may be a plurality of heat sink interconnects. The plurality of interconnects 342 may vertically overlap with the integrated device 103. The plurality of interconnects 342 may or may not touch the plurality of interconnects 142. In some implementations, one or more of the interconnects from the plurality of interconnects 342 may be free of any electrical connection with circuits and/or electrical components of the package 700, the package 701, the package 203 and/or the integrated device 103. In some implementations, the dielectric layer 140 (e.g., interposer dielectric layer) may include silicon, glass or an organic dielectric layer. In some implementations, the dielectric layer 140 may include prepreg and/or polyimide.

The encapsulation layer 106 is coupled to the metallization portion 102, the substrate 304 and the metallization portion 102. The encapsulation layer 106 may at least partially encapsulate the integrated device 103, the plurality of post interconnects 608 and the substrate 104. Thus, the integrated device 103, the plurality of post interconnects 608 and/or the substrate 304 may be located at least partially in the encapsulation layer 106. The encapsulation layer 106 may include a mold, a resin, an epoxy and/or a filler. The encapsulation layer 106 may be located between the metallization portion 102 and the substrate 304. The plurality of post interconnects 608 may be located laterally to the integrated device 103.

The plurality of post interconnects 608 are coupled to the substrate 304 and the metallization portion 102. The plurality of post interconnects 608 may be coupled to and touch (i) the plurality of metallization interconnects 122 of the metallization portion 102 and (ii) the plurality of interconnects 142 of the substrate 304.

The integrated device 103 is coupled to and touch the metallization portion 102. The integrated device 103 is coupled to the plurality of metallization interconnects 122 of the metallization portion 102. The integrated device 103 is coupled to the substrate 304 through a thermal interface material (TIM) 306. For example, a back side of the integrated device 103 may be coupled to the plurality of interconnects 342 of the substrate 304 through the thermal interface material (TIM) 306. As mentioned above, a part of the substrate 304 may be configured to operate as a heat sink. The back side of the integrated device 103 may be the side that includes a die substrate (e.g., silicon substrate). A portion of the integrated device 103 may or may not vertically overlap with a portion of the package 203.

An electrical path between the integrated device 103 and the package 203 may include (i) the metallization portion 102, (ii) the plurality of post interconnects 608, (iii) the substrate 304, and/or (iv) the plurality of solder interconnects 202. For example, an electrical path between the integrated device 103 and the package 203 may include (i) at least one metallization interconnect from the plurality of metallization interconnects 122, (ii) at least one post interconnect from the plurality of post interconnects 608, (iii) at least one interconnect from the plurality of interconnects 142 and/or (iv) at least one solder interconnect from the plurality of solder interconnects 202.

The configuration of the package 700 provides a package with improved heat dissipation and/or thermal performance, which helps improve the performance of the package 701 and/or the package 700. This is possible because the substrate 304 and/or the package 203 is offset from the integrated device 103, and a part of the substrate 304 is used as heat sink. In some implementations, the use of the plurality of post interconnects 608 helps provide high aspect ratio interconnects that can extend through the encapsulation layer 106, and may be useful for integrated device 103 with relatively low thicknesses.

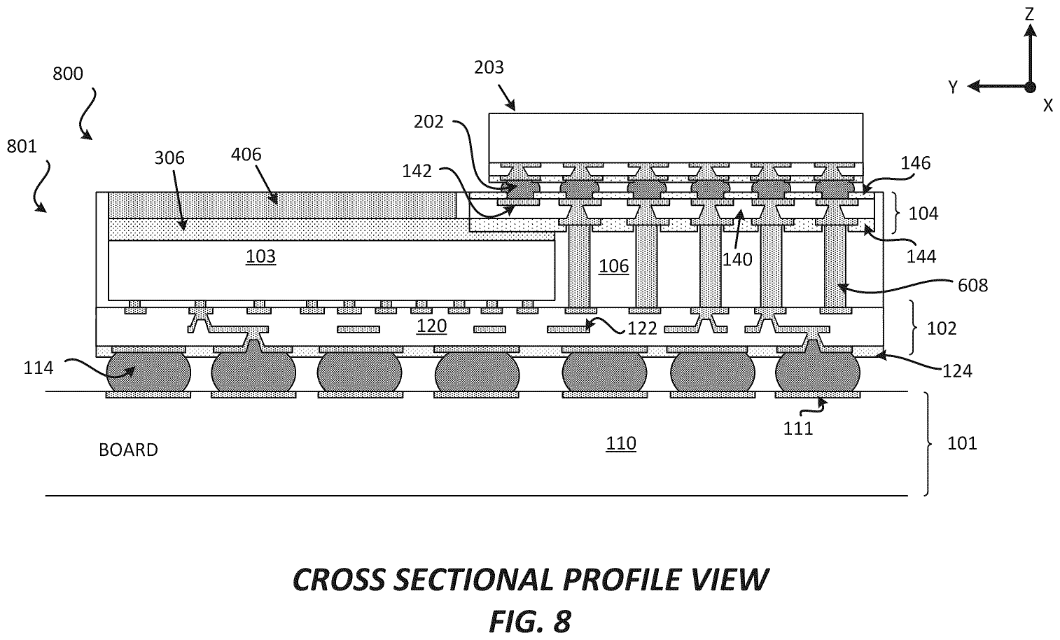

FIG. 8 illustrates a cross sectional profile view of a package 800 that includes a package 801 and the package 203. The package 800 may be a package on package (POP). The package 203 is coupled to the package 801 through a plurality of solder interconnects 202. The package 203 may include a memory package (e.g., memory chip). The package 203 may include at least one integrated device, a metallization portion, a substrate, an interposer, and/or an encapsulation layer. The package 203 is coupled to a substrate 104 through the plurality of solder interconnects 202. The plurality of solder interconnects 202 may be coupled to the plurality of interconnects 142 of the substrate 104 and a plurality of interconnects of the package 203. In some implementations, the plurality of solder interconnects 202 may be coupled to interconnects of a substrate of the package 203. In some implementations, the plurality of solder interconnects 202 may be coupled to metallization interconnects of a metallization portion of the package 203. Instead of a package being coupled to the substrate 104, another integrated device may be coupled to the substrate 104. The package 203 and/or the substrate 104 may be offset from the integrated device 103.

The package 801 is coupled to a board 101 through a plurality of solder interconnects 114. The package 801 includes a metallization portion 102, an integrated device 103, a substrate 104, a plurality of post interconnects 608, an encapsulation layer 106, a thermal interface material (TIM) 306 and a heat sink 406. The metallization portion 102 includes at least one dielectric layer 120, a plurality of metallization interconnects 122 and a solder resist layer 124. The substrate 104 may be an interposer (e.g., package interposer). The substrate 104 may include a dielectric layer 140 (e.g., interposer dielectric layer), a plurality of interconnects 142 (e.g., interposer interconnects), a solder resist layer 144 and a solder resist layer 146. In some implementations, the dielectric layer 140 (e.g., interposer dielectric layer) may include silicon, glass or an organic dielectric layer. The substrate 104 has a lateral size that is less than the lateral size of the metallization portion 102. In some implementations, the dielectric layer 140 may include prepreg and/or polyimide.

The encapsulation layer 106 is coupled to the metallization portion 102, the substrate 104 and the metallization portion 102. The encapsulation layer 106 may at least partially encapsulate the integrated device 103, the plurality of post interconnects 608, the substrate 104 and the heat sink 406. Thus, the integrated device 103, the plurality of post interconnects 608, the substrate 104, the thermal interface material (TIM) 306 and/or the heat sink 406 may be located at least partially in the encapsulation layer 106. The encapsulation layer 106 may include a mold, a resin, an epoxy and/or a filler. The encapsulation layer 106 may be located between the metallization portion 102 and the substrate 104. The post interconnects 608 may be located laterally to the integrated device 103. The integrated device 103 may vertically overlap (i) with at least a portion of the heat sink 406, (ii) with at least a portion of the substrate 104, and/or (iii) with at least a portion of the package 203.

The plurality of post interconnects 608 are coupled to the substrate 104 and the metallization portion 102. The plurality of post interconnects 608 may be coupled to and touch (i) the plurality of metallization interconnects 122 of the metallization portion 102 and (ii) the plurality of interconnects 142 of the substrate 104.

The integrated device 103 is coupled to and touch the metallization portion 102. The integrated device 103 is coupled to the plurality of metallization interconnects 122 of the metallization portion 102. The integrated device 103 may be coupled to the substrate 104 through a thermal interface material (TIM) 306. The integrated device 103 may be coupled to the heat sink 406 through a thermal interface material (TIM) 306. For example, a back side of the integrated device 103 is coupled to the heat sink 406 through the thermal interface material (TIM) 306. The back side of the integrated device 103 may be the side that includes a die substrate (e.g., silicon substrate). A portion of the integrated device 103 may vertically overlap with a portion of the package 203 and/or a portion of the substrate 104. In some implementations, the integrated device 103 may not vertically overlap with the package 203. In some implementations, the integrated device 103 may not vertically overlap with the substrate 104. The heat sink 406 may be located laterally to the substrate 104.

An electrical path between the integrated device 103 and the package 203 may include (i) the metallization portion 102, (ii) the plurality of post interconnects 608, (iii) the substrate 104, and/or (iv) the plurality of solder interconnects 202. For example, an electrical path between the integrated device 103 and the package 203 may include (i) at least one metallization interconnect from the plurality of metallization interconnects 122, (ii) at least one post interconnect from the plurality of post interconnects 608, (iii) at least one interconnect from the plurality of interconnects 142 and/or (iv) at least one solder interconnect from the plurality of solder interconnects 202.

The configuration of the package 800 provides a package with improved heat dissipation and/or thermal performance, which helps improve the performance of the package 801 and/or the package 800. This is possible because the substrate 104 and/or the package 203 is offset from the integrated device 103, and a heat sink 406 is provided to help dissipate heat away from the integrated device 103.

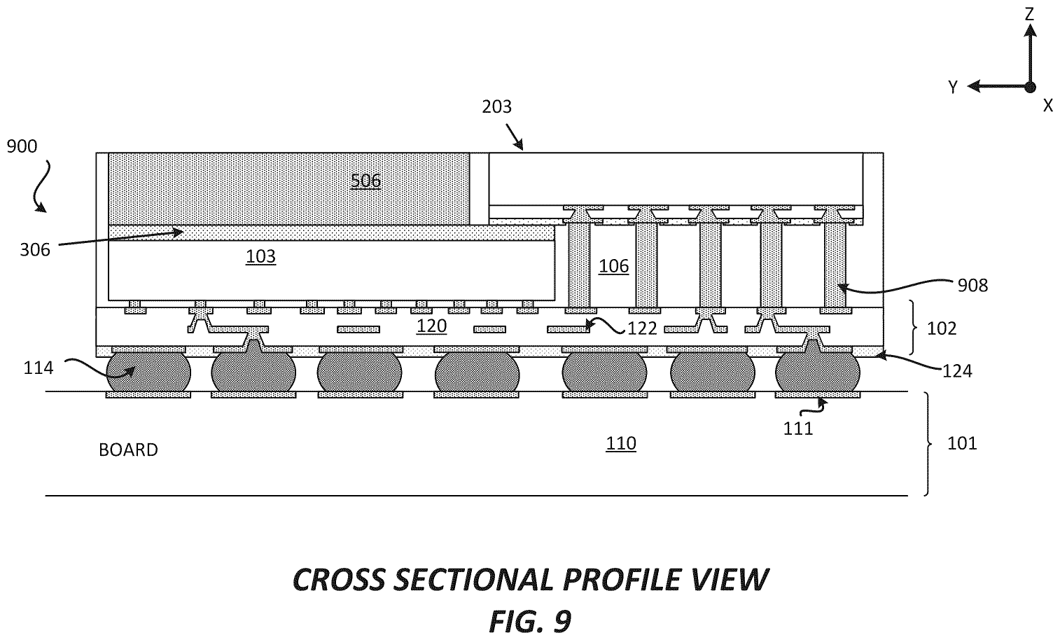

FIG. 9 illustrates a cross sectional profile view of a package 900 that includes an integrated device and a plurality of post interconnects. The package 900 is coupled to a board 101 through a plurality of solder interconnects 114. The package 900 includes a metallization portion 102, an integrated device 103, a plurality of post interconnects 908, a package 203, an encapsulation layer 106, a thermal interface material (TIM) 306 and a heat sink 506. The metallization portion 102 includes at least one dielectric layer 120, a plurality of metallization interconnects 122 and a solder resist layer 124. The package 203 may include at least one integrated device, a metallization portion, a substrate, an interposer, and/or an encapsulation layer. The package 203 may include a memory package (e.g., memory chip).

The encapsulation layer 106 is coupled to the metallization portion 102, the substrate 104 and the metallization portion 102. The encapsulation layer 106 may at least partially encapsulate the integrated device 103, the plurality of post interconnects 908 and the heat sink 506. Thus, the integrated device 103, the plurality of post interconnects 908, the thermal interface material (TIM) 306 and/or the heat sink 406 may be located at least partially in the encapsulation layer 106. The encapsulation layer 106 may include a mold, a resin, an epoxy and/or a filler. The encapsulation layer 106 may be located between the metallization portion 102 and the package 203.

The plurality of post interconnects 908 are coupled to the package 203 and the metallization portion 102. The plurality of post interconnects 908 may be coupled to and touch (i) the plurality of metallization interconnects 122 of the metallization portion 102 and (ii) interconnects of the package 203. In some implementations, interconnects of the package 203 may include metallization interconnects, substrate interconnects, and/or pad interconnects of the package 203.

The integrated device 103 is coupled to and touch the metallization portion 102. The integrated device 103 is coupled to the plurality of metallization interconnects 122 of the metallization portion 102. The integrated device 103 may be coupled to the package 203 through a thermal interface material (TIM) 306. The integrated device 103 may be coupled to the heat sink 506 through a thermal interface material (TIM) 306. For example, a back side of the integrated device 103 is coupled to the heat sink 506 through the thermal interface material (TIM) 306. The back side of the integrated device 103 may be coupled to the package 203 through the thermal interface material (TIM) 306. The back side of the integrated device 103 may be the side that includes a die substrate (e.g., silicon substrate). A portion of the integrated device 103 may vertically overlap with a portion of the package 203. In some implementations, the integrated device 103 may not vertically overlap with the package 203. The heat sink 506 may be located laterally to the package 203. The heat sink 506 may vertically overlap with the integrated device 103.

An electrical path between the integrated device 103 and the package 203 may include (i) the metallization portion 102 and (ii) the plurality of post interconnects 908. For example, an electrical path between the integrated device 103 and the package 203 may include (i) at least one metallization interconnect from the plurality of metallization interconnects 122 and (ii) at least one post interconnect from the plurality of post interconnects 908.

The configuration of the package 900 provides a package with improved heat dissipation and/or thermal performance, which helps improve the performance of the package 900. In comparison to the package 600, the package 700 and/or the package 800, the package 900 bypasses the use of a substrate (e.g., 104, 304), which can help reduce the overall size of the package.

In some implementations, the plurality of post interconnects 908 may be used when the integrated device 103 is on the relatively thinner side, while the plurality of wire bonds 108 may be used when the integrated device 103 is on the relatively thicker side. In some implementations, the use of the substrate (e.g., 104, 304) in the various packages described in the disclosure may help reduce the overall thickness of the metallization portion 102, which in turn may help reduce the overall size and/or thickness of the packages.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 600) may be implemented in a radio frequency (RF) package. The RF package may be a radio frequency front end (RFFE) package. A package (e.g., 200, 600) may be configured to provide Wireless Fidelity (WiFi) communication and/or cellular communication (e.g., 2G, 3G, 4G, 5G). The packages (e.g., 200, 600) may be configured to support Global System for Mobile (GSM) Communications, Universal Mobile Telecommunications System (UMTS), and/or Long-Term Evolution (LTE). The packages (e.g., 200, 600) may be configured to transmit and receive signals having different frequencies and/or communication protocols.

### Exemplary Sequence for Fabricating a Package Comprising Wire Bonds

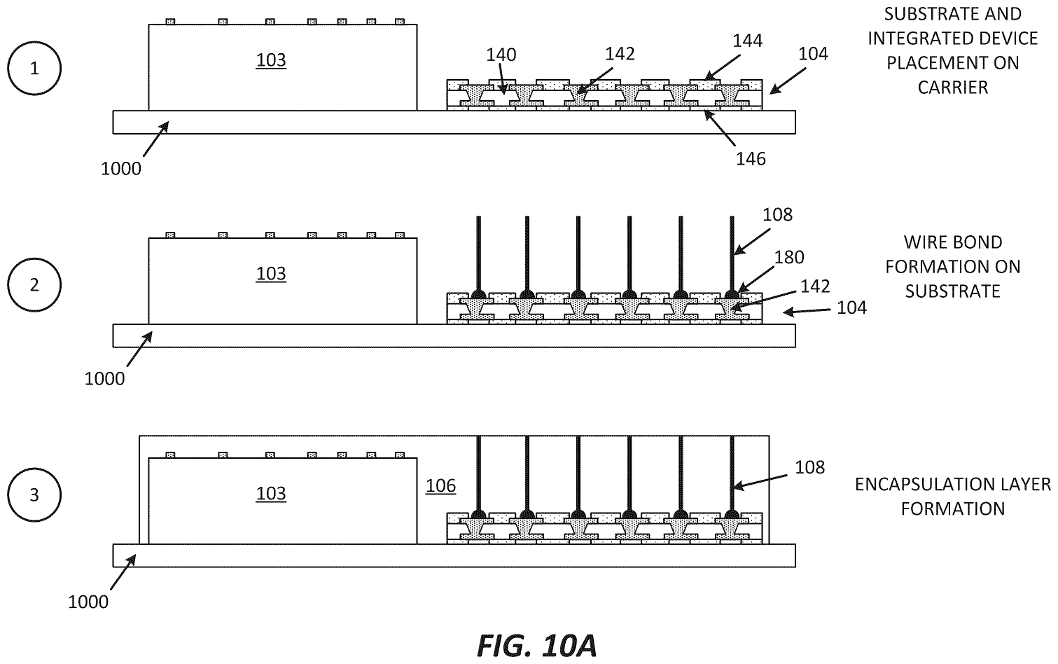

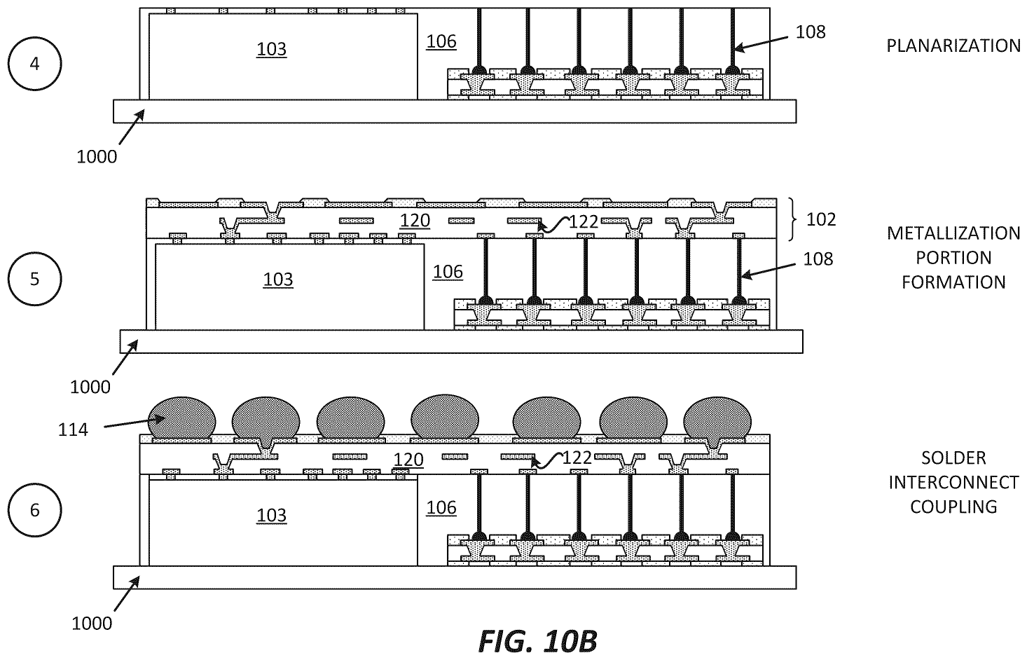

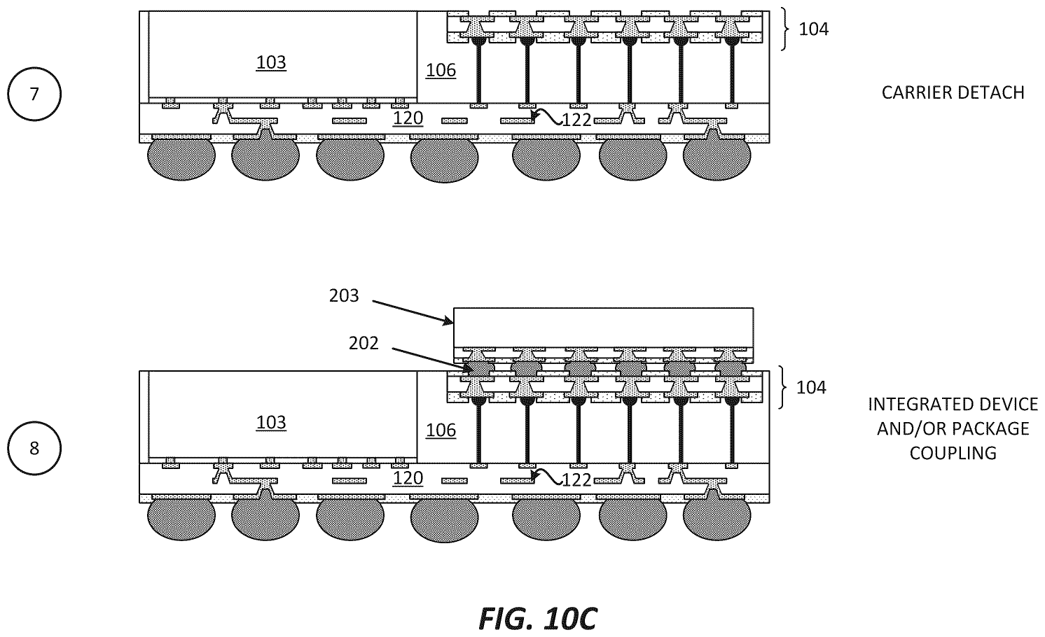

In some implementations, fabricating a package includes several processes. FIGS. 10A-10C illustrate an exemplary sequence for providing or fabricating a package. In some implementations, the sequence of FIGS. 10A-10C may be used to provide or fabricate the package 200. However, the process of FIGS. 10A-10C may be used to fabricate any of the packages described in the disclosure.

It should be noted that the sequence of FIGS. 10A-10C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 10A, illustrates a state after a substrate 104 and an integrated device 103 are provided, placed and/or coupled to a carrier 1000. The carrier 1000 may include glass. An adhesive may be used to place and couple the substrate 104 and the integrated device 103 to the carrier 1000. The substrate 104 may include at least one dielectric layer 140, a plurality of interconnects 142, a solder resist layer 144 and a solder resist layer 146. A back side of the integrated device 103 may be coupled to the carrier 1000.

Stage 2 illustrates a state after a plurality of wire bonds 108 are formed and coupled to the substrate 104. The plurality of wire bonds 108 may include a plurality of ball bonds 180. A wire bonding process may be used to couple the plurality of wire bonds 108 to the substrate 104. The plurality of ball bonds 180 may be coupled to the plurality of interconnects 142 of the substrate 104.

Stage 3 illustrates a state after an encapsulation layer 106 is provided and coupled to the carrier 1000. The encapsulation layer 106 may at least partially encapsulate the integrated device 103, the substrate 104 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off.

Stage 4 of FIG. 10B, illustrates a state a planarization process of the encapsulation layer 106. A portion of the encapsulation layer 106 and a portion of the plurality of wire bonds 108 may be removed and/or grinded off.

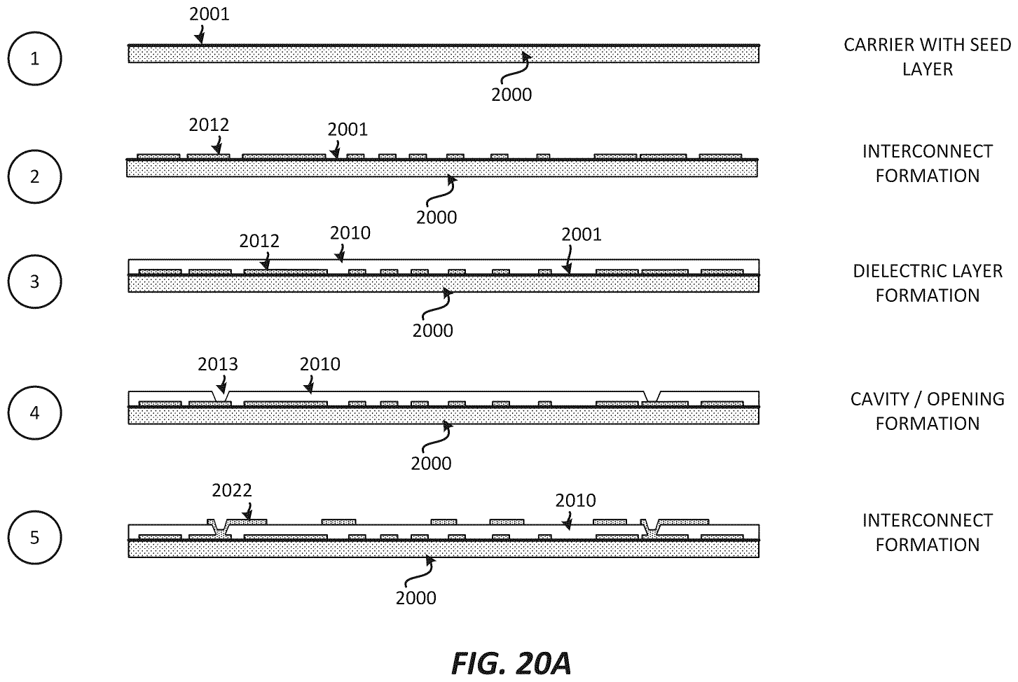

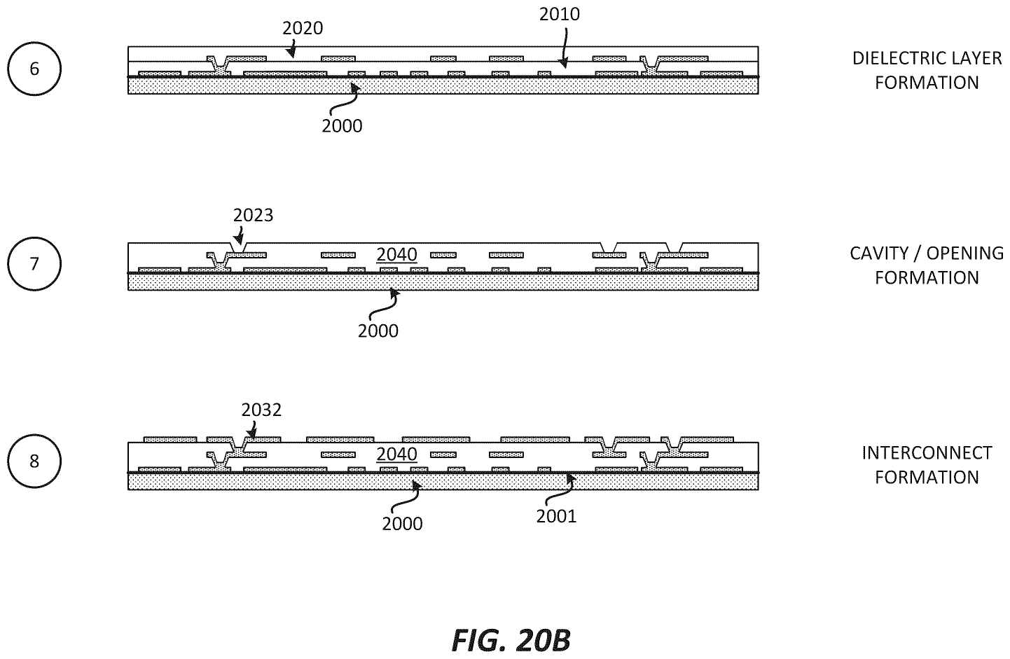

Stage 5 illustrates a state after a metallization portion 102 is formed and coupled to the integrated device 103, the encapsulation layer 106 and the plurality of wire bonds 108. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 6 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 7 of FIG. 10C, illustrates a state after the carrier 1000 is detached from the encapsulation layer 106, the integrated device 103 and the substrate 104.

Stage 8 illustrates a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 8 may illustrate a package 200 that includes an integrated device and a plurality of wire bonds.

### Exemplary Sequence for Fabricating a Package Comprising Wire Bonds

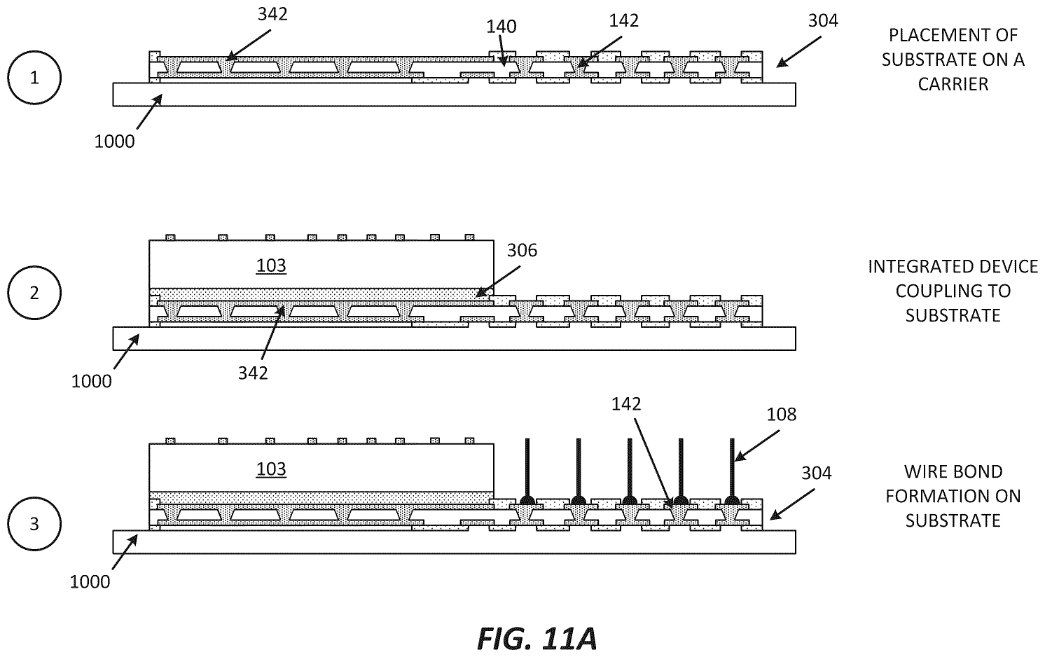

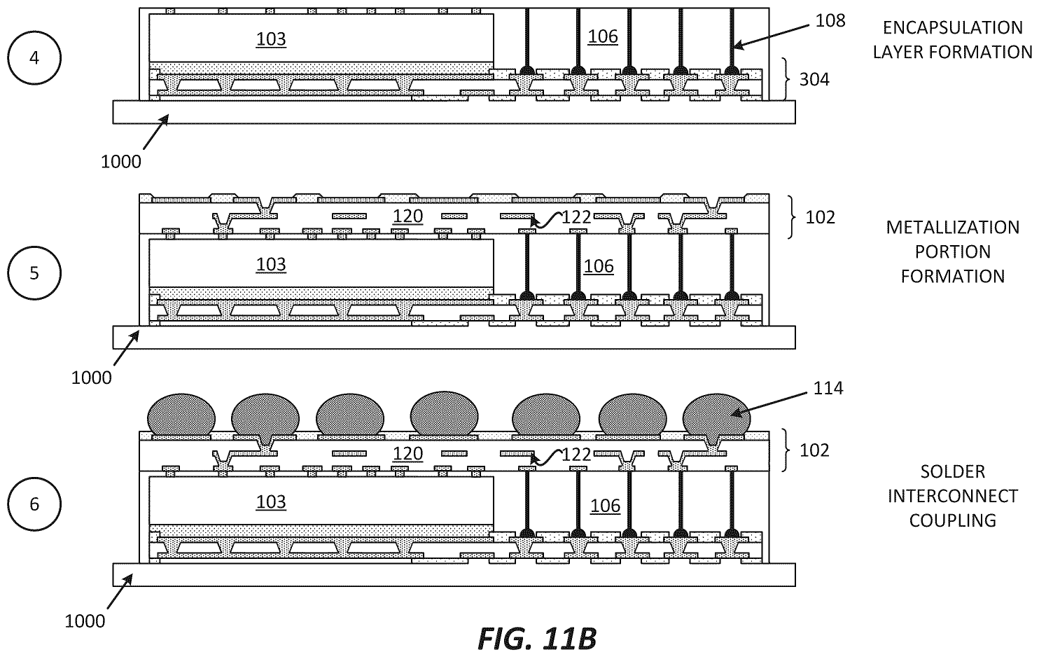

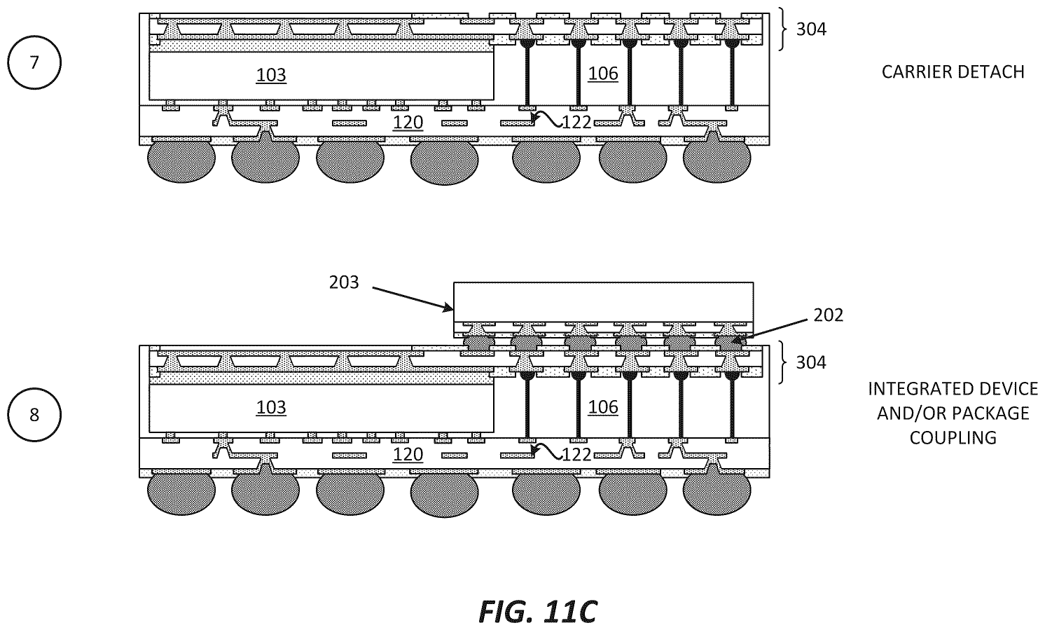

In some implementations, fabricating a package includes several processes. FIGS. 11A-11C illustrate an exemplary sequence for providing or fabricating a package. In some implementations, the sequence of FIGS. 11A-11C may be used to provide or fabricate the package 300. However, the process of FIGS. 11A-11C may be used to fabricate any of the packages described in the disclosure.

It should be noted that the sequence of FIGS. 11A-11C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11A, illustrates a state after a substrate 304 is provided, placed and/or coupled to a carrier 1000. The carrier 1000 may include glass. An adhesive may be used to place and couple the substrate 304 to the carrier 1000. The substrate 304 may include at least one dielectric layer 140, a plurality of interconnects 142, a plurality of interconnects 342, a solder resist layer 144 and a solder resist layer 146. The plurality of interconnects 342 may be configured to operate as a heat sink.

Stage 2 illustrates a state after an integrated device 103 is coupled to the substrate 304 through a thermal interface material (TIM) 306. A back side of the integrated device 103 may be coupled to the substrate 304 through the thermal interface material (TIM) 306. For example, a back side of the integrated device 103 may be coupled to the plurality of interconnects 342 through the thermal interface material (TIM) 306.

Stage 3 illustrates a state after a plurality of wire bonds 108 are formed and coupled to the substrate 304. The plurality of wire bonds 108 may include a plurality of ball bonds 180. A wire bonding process may be used to couple the plurality of wire bonds 108 to the substrate 304. The plurality of ball bonds 180 may be coupled to the plurality of interconnects 142 of the substrate 304.

Stage 4, as shown in FIG. 11B, illustrates a state after an encapsulation layer 106 is provided and coupled to the carrier 1000. The encapsulation layer 106 may at least partially encapsulate the integrated device 103, the substrate 304 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 5 illustrates a state after a metallization portion 102 is formed and coupled to the integrated device 103, the encapsulation layer 106 and the plurality of wire bonds 108. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 6 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 7 of FIG. 11C, illustrates a state after the carrier 1000 is detached from the encapsulation layer 106, the integrated device 103 and the substrate 304.

Stage 8 illustrates a state after a package 203 is coupled to the substrate 304 through a plurality of solder interconnects 202. A solder reflow process may be used to couple the plurality of solder interconnects 202 to interconnects of the package 203 and the plurality of interconnects 142 of the substrate 304. Stage 8 may illustrate a package 300 that includes an integrated device and a plurality of wire bonds.

### Exemplary Sequence for Fabricating a Package Comprising Wire Bonds

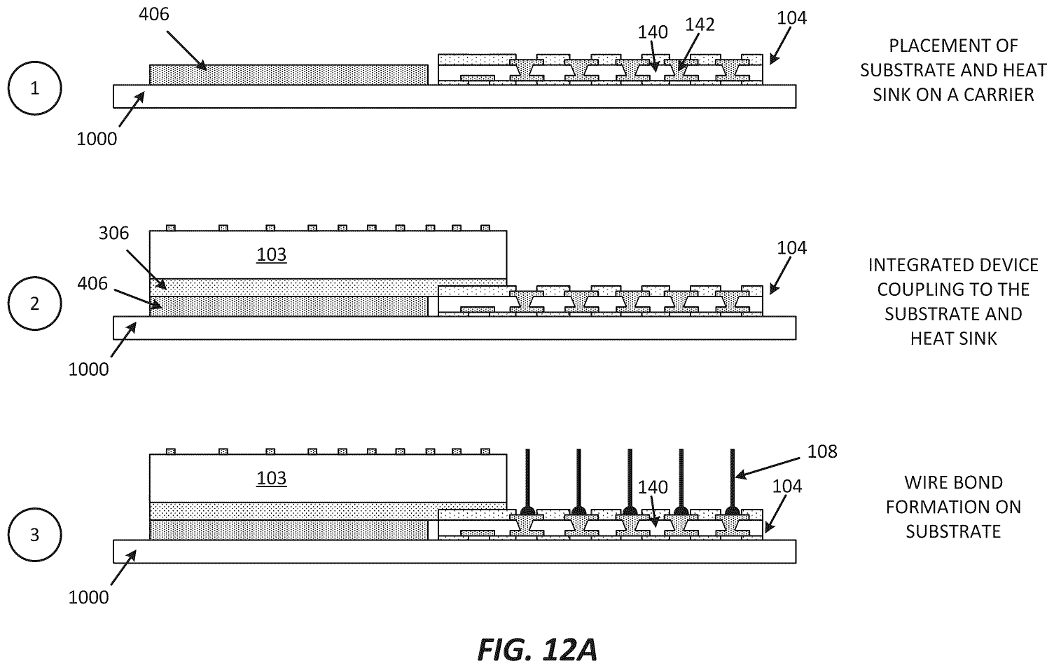

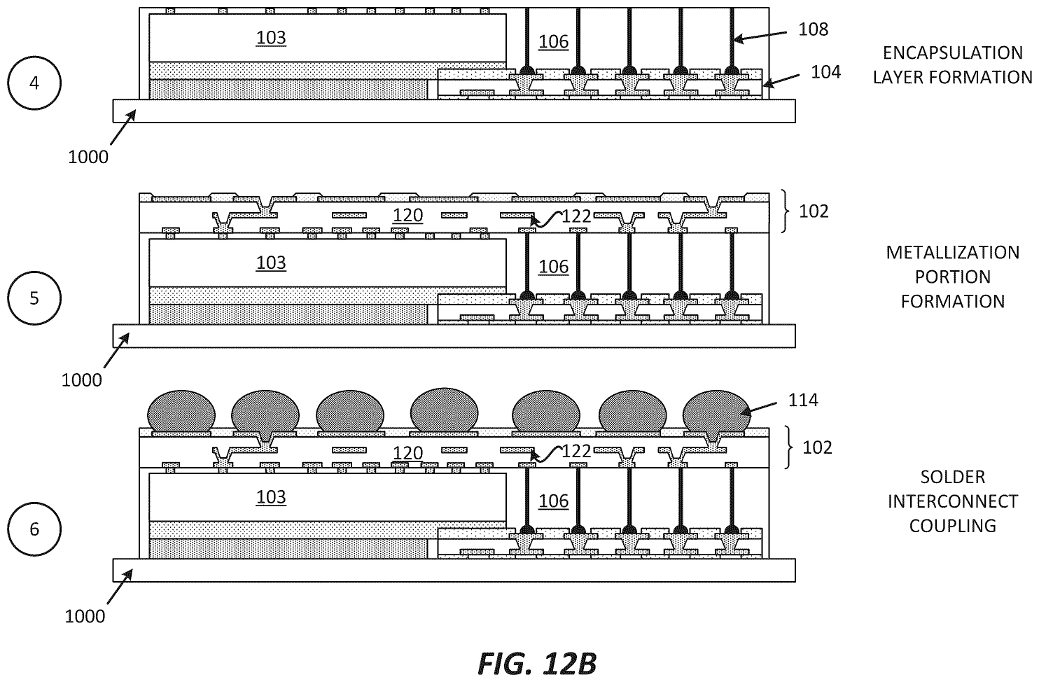

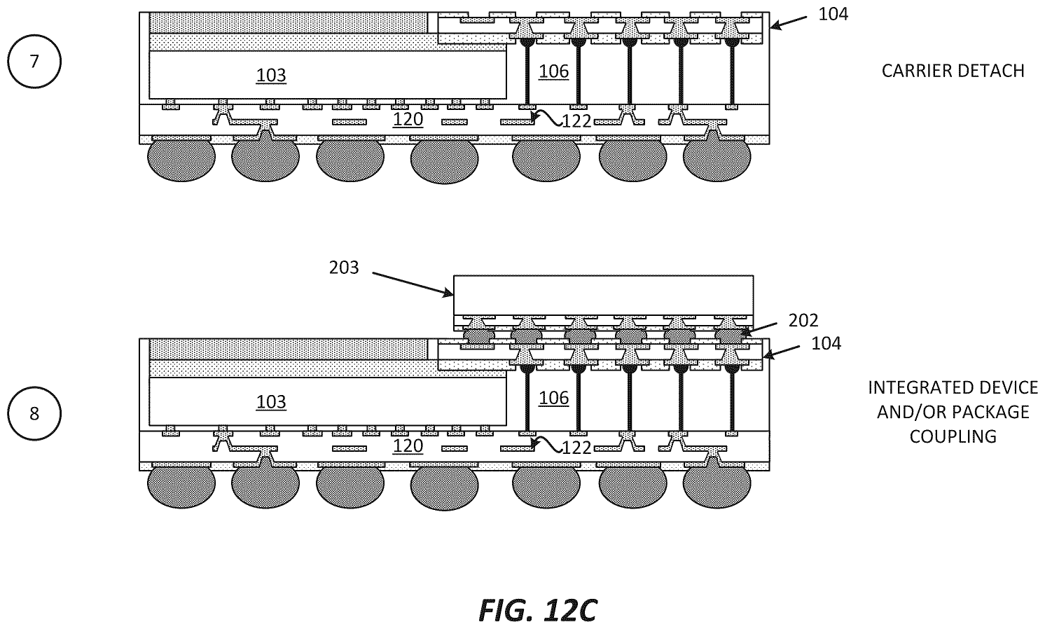

In some implementations, fabricating a package includes several processes. FIGS. 12A-12C illustrate an exemplary sequence for providing or fabricating a package. In some implementations, the sequence of FIGS. 12A-12C may be used to provide or fabricate the package 400. However, the process of FIGS. 12A-12C may be used to fabricate any of the packages described in the disclosure.

It should be noted that the sequence of FIGS. 12A-12C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 12A, illustrates a state after a substrate 104 is provided, placed and/or coupled to a carrier 1000. The carrier 1000 may include glass. An adhesive may be used to place and couple the substrate 104 to the carrier 1000. The substrate 104 may include at least one dielectric layer 140, a plurality of interconnects 142, a solder resist layer 144 and a solder resist layer 146. A heat sink 406 may also be provided, placed and/or coupled to the carrier 1000. An adhesive may be used to place and couple the heat sink 406 to the carrier 1000.

Stage 2 illustrates a state after an integrated device 103 is coupled to the substrate 104 and the heat sink 406 through a thermal interface material (TIM) 306. A back side of the integrated device 103 may be coupled to the substrate 104 and the heat sink 406 through the thermal interface material (TIM) 306.

Stage 3 illustrates a state after a plurality of wire bonds 108 are formed and coupled to the substrate 104. The plurality of wire bonds 108 may include a plurality of ball bonds 180. A wire bonding process may be used to couple the plurality of wire bonds 108 to the substrate 104. The plurality of ball bonds 180 may be coupled to the plurality of interconnects 142 of the substrate 104.

Stage 4, as shown in FIG. 12B, illustrates a state after an encapsulation layer 106 is provided and coupled to the carrier 1000. The encapsulation layer 106 may at least partially encapsulate the integrated device 103, the substrate 104, the heat sink 406, the thermal interface material (TIM) 306 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 5 illustrates a state after a metallization portion 102 is formed and coupled to the integrated device 103, the encapsulation layer 106 and the plurality of wire bonds 108. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 6 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 7 of FIG. 12C, illustrates a state after the carrier 1000 is detached from the encapsulation layer 106, the integrated device 103 and the substrate 104.

Stage 8 illustrates a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 8 may illustrate a package 400 that includes an integrated device and a plurality of wire bonds.

### Exemplary Sequence for Fabricating a Package Comprising Wire Bonds

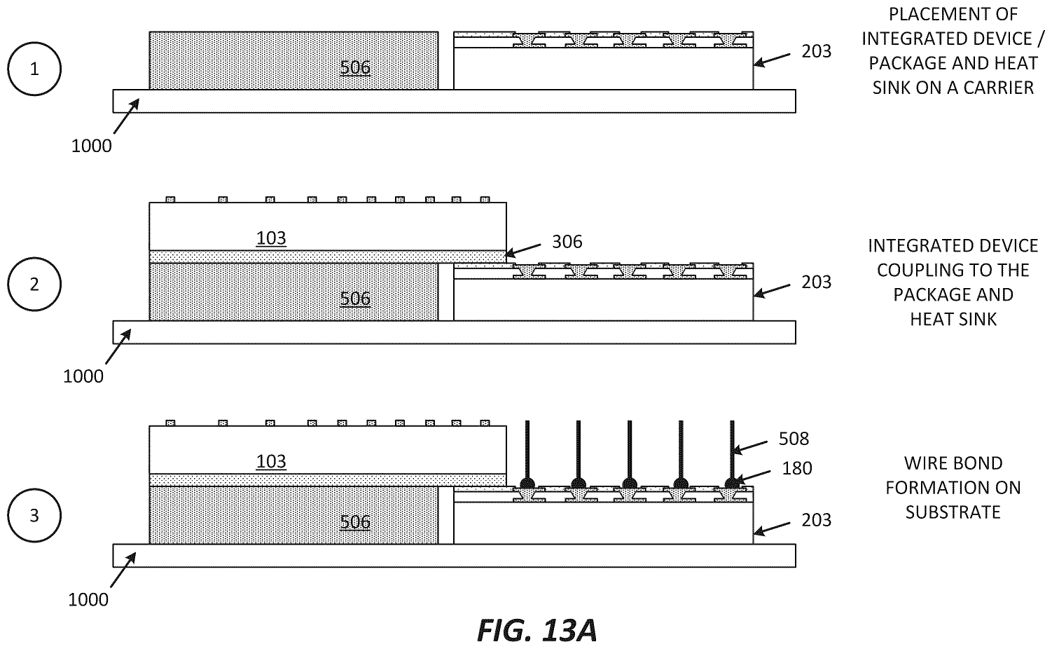

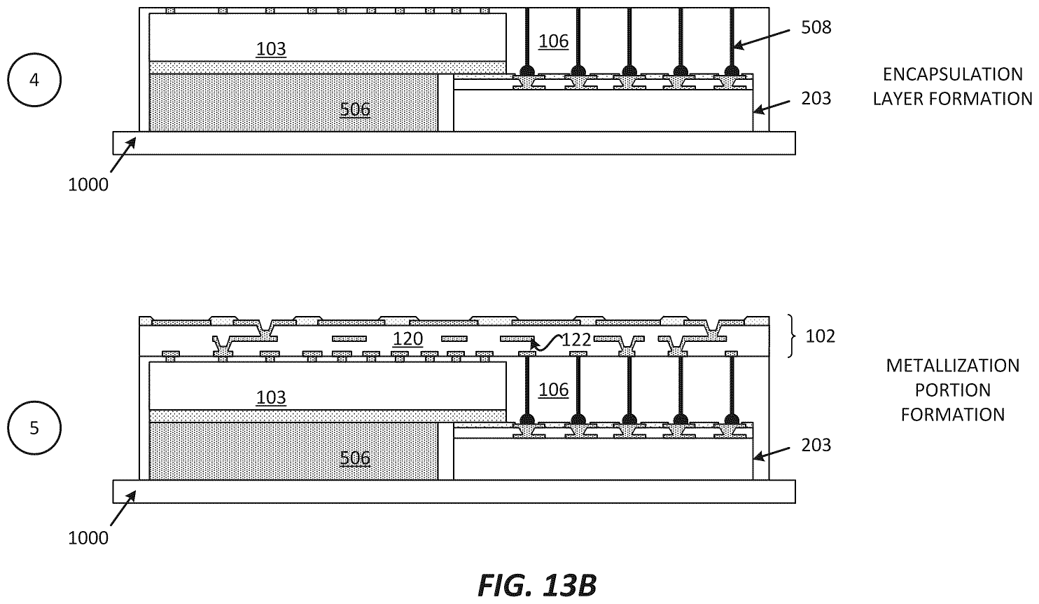

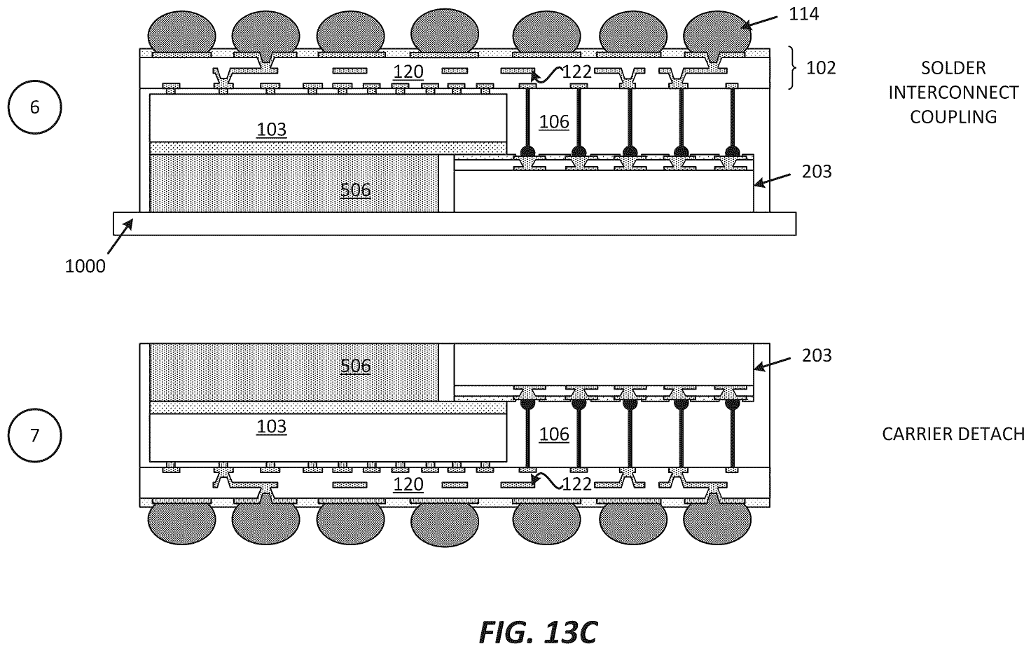

In some implementations, fabricating a package includes several processes. FIGS. 13A-13C illustrate an exemplary sequence for providing or fabricating a package. In some implementations, the sequence of FIGS. 13A-13C may be used to provide or fabricate the package 500. However, the process of FIGS. 13A-13C may be used to fabricate any of the packages described in the disclosure.

It should be noted that the sequence of FIGS. 13A-13C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 13A, illustrates a state after a package 203 is provided, placed and/or coupled to a carrier 1000. The carrier 1000 may include glass. An adhesive may be used to place and couple the package 203 to the carrier 1000. A back side of the package 203 may be coupled to the carrier 1000. A heat sink 506 may also be provided, placed and/or coupled to the carrier 1000. An adhesive may be used to place and couple the heat sink 506 to the carrier 1000.

Stage 2 illustrates a state after an integrated device 103 is coupled to the package 203 and the heat sink 506 through a thermal interface material (TIM) 306. A back side of the integrated device 103 may be coupled to the package 203 and the heat sink 406 through the thermal interface material (TIM) 306.

Stage 3 illustrates a state after a plurality of wire bonds 508 are formed and coupled to the package 203. The plurality of wire bonds 508 may include a plurality of ball bonds 180. A wire bonding process may be used to couple the plurality of wire bonds 108 to the package 203. The plurality of ball bonds 180 may be coupled to interconnects of the package 203 (e.g., metallization interconnects, substrate interconnects, pillar interconnect, and/or pad interconnects of the package 203).

Stage 4, as shown in FIG. 13B, illustrates a state after an encapsulation layer 106 is provided and coupled to the carrier 1000. The encapsulation layer 106 may at least partially encapsulate the integrated device 103, the package 203, the heat sink 506, the thermal interface material (TIM) 306 and the plurality of wire bonds 508. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 5 illustrates a state after a metallization portion 102 is formed and coupled to the integrated device 103, the encapsulation layer 106 and the plurality of wire bonds 108. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 6 of FIG. 13C, illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 7 illustrates a state after the carrier 1000 is detached from the encapsulation layer 106, the integrated device 103 and the package 203. Stage 7 may illustrate the package 500.

### Exemplary Flow Diagram of a Method for Fabricating a Package Comprising Wire Bonds

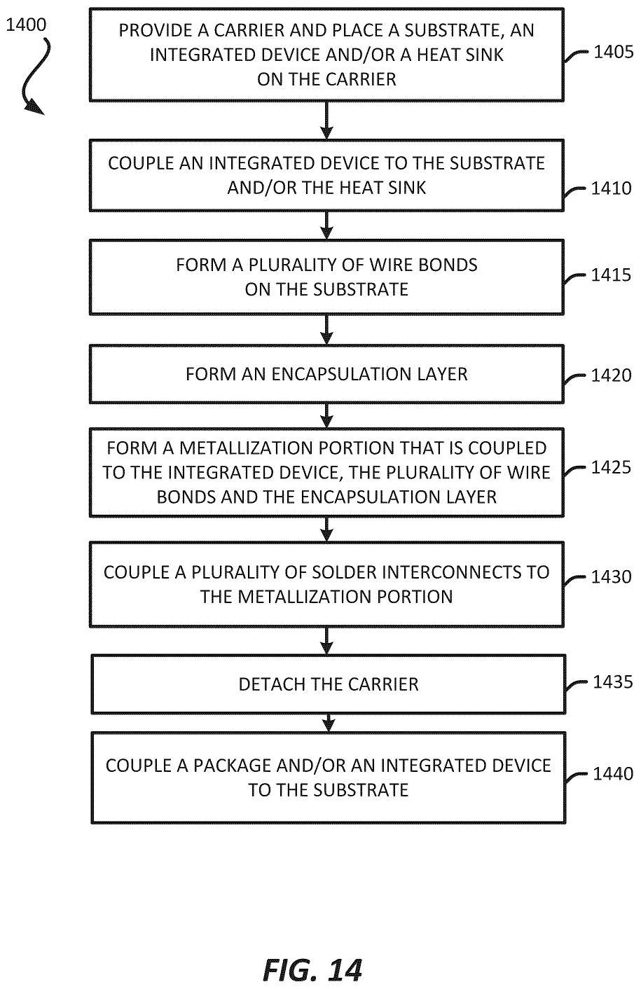

In some implementations, fabricating a package includes several processes. FIG. 14 illustrates an exemplary flow diagram of a method 1400 for providing or fabricating a package. In some implementations, the method 1400 of FIG. 14 may be used to provide or fabricate the package 200, the package 300, and/or the package 400 described in the disclosure. However, the method 1400 may be used to provide or fabricate any of the packages described in the disclosure.

It should be noted that the method 1400 of FIG. 14 may combine one or more processes in order to simplify and/or clarify the method for providing or fabricating a package. In some implementations, the order of the processes may be changed or modified.

The method provides (at 1405) a carrier and couples a substrate, a heat sink and/or an integrated device to the carrier. Stage 1 of FIG. 12A, illustrates and describes an example of a state after a substrate 104 is provided, placed and/or coupled to a carrier 1000. The carrier 1000 may include glass. An adhesive may be used to place and couple the substrate 104 to the carrier 1000. The substrate 104 may include at least one dielectric layer 140, a plurality of interconnects 142, a solder resist layer 144 and a solder resist layer 146. A heat sink 406 may also be provided, placed and/or coupled to the carrier 1000. An adhesive may be used to place and couple the heat sink 406 to the carrier 1000.

The method may couple (at 1410) an integrated device to the substrate and/or the heat sink. Stage 2 of FIG. 12A, illustrates and describes an example of a state after an integrated device 103 is coupled to the substrate 104 and the heat sink 406 through a thermal interface material (TIM) 306. A back side of the integrated device 103 may be coupled to the substrate 104 and the heat sink 406 through the thermal interface material (TIM) 306.

The method forms (at 1415) a plurality of wire bonds on a substrate. Stage 3 of FIG. 12A, illustrates a state after a plurality of wire bonds 108 are formed and coupled to the substrate 104. The plurality of wire bonds 108 may include a plurality of ball bonds 180. A wire bonding process may be used to couple the plurality of wire bonds 108 to the substrate 104. The plurality of ball bonds 180 may be coupled to the plurality of interconnects 142 of the substrate 104.

The method forms (at 1420) an encapsulation layer. Stage 4 of FIG. 12B, illustrates and describes an example of a state after an encapsulation layer 106 is provided and coupled to the carrier 1000. The encapsulation layer 106 may at least partially encapsulate the integrated device 103, the substrate 104, the heat sink 406, the thermal interface material (TIM) 306 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off.

The method forms (at 1425) a metallization portion that is coupled to the integrated device, the substrate and/or the heat sink. Stage 5 of FIG. 12B, illustrates and describes an example of a state after a metallization portion 102 is formed and coupled to the integrated device 103, the encapsulation layer 106 and the plurality of wire bonds 108. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

The method couples (at 1430) a plurality of solder interconnects to the metallization portion. Stage 6 of FIG. 12B, illustrates and describes an example of a state after a plurality of solder interconnects 114 are coupled to the metallization portion 102. A solder reflow process may be used to couple the plurality of solder interconnects 114 to the plurality of metallization interconnects 122 of the metallization portion 102.

The method detaches (at 1435) the carrier. Stage 7 of FIG. 12C, illustrates and describes an example of a state after the carrier 1000 is detached from the encapsulation layer 106, the integrated device 103 and the substrate 104.

The method couples (at 1440) an integrated device and/or a package to the substrate. Stage 8 of FIG. 12C, illustrates and describes an example of a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 8 may illustrate a package 400 that includes an integrated device and a plurality of wire bonds.

### Exemplary Sequence for Fabricating a Package Comprising Post Interconnects

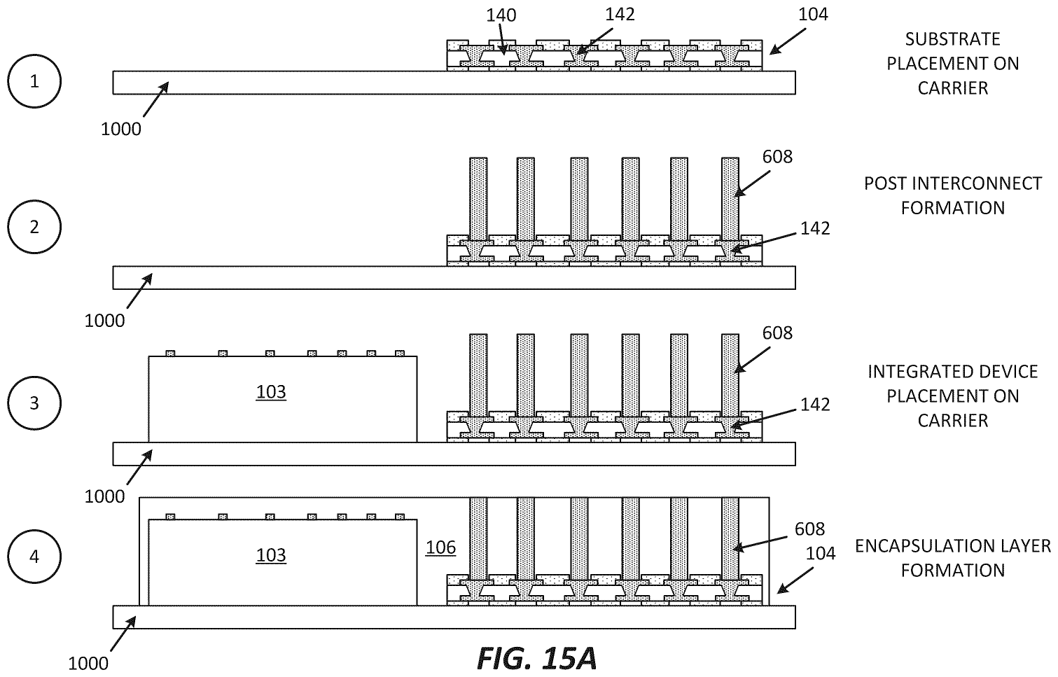

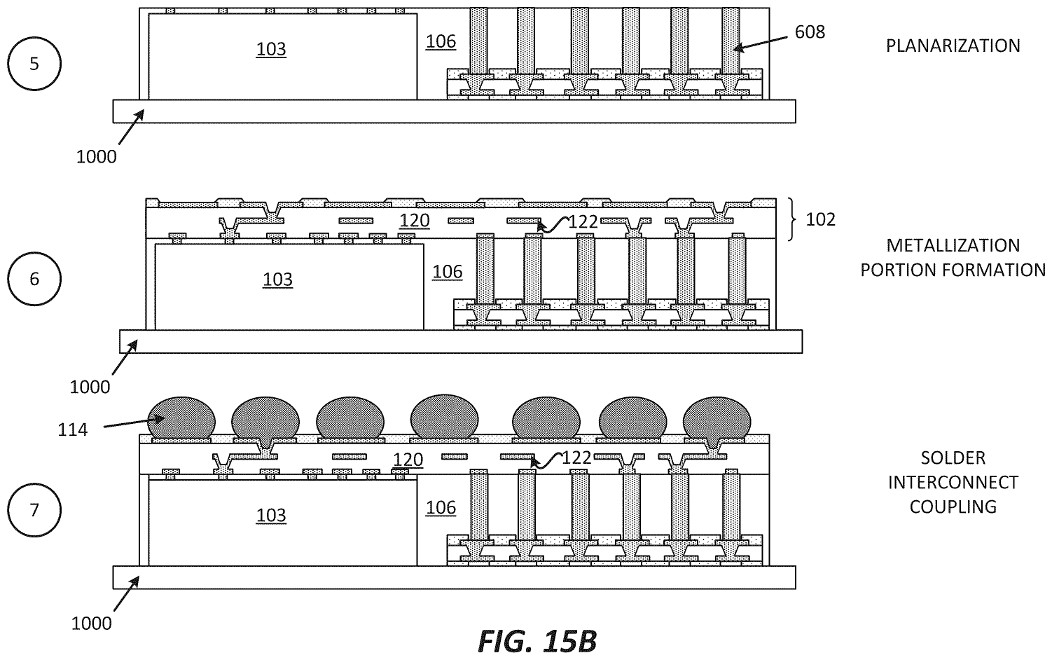

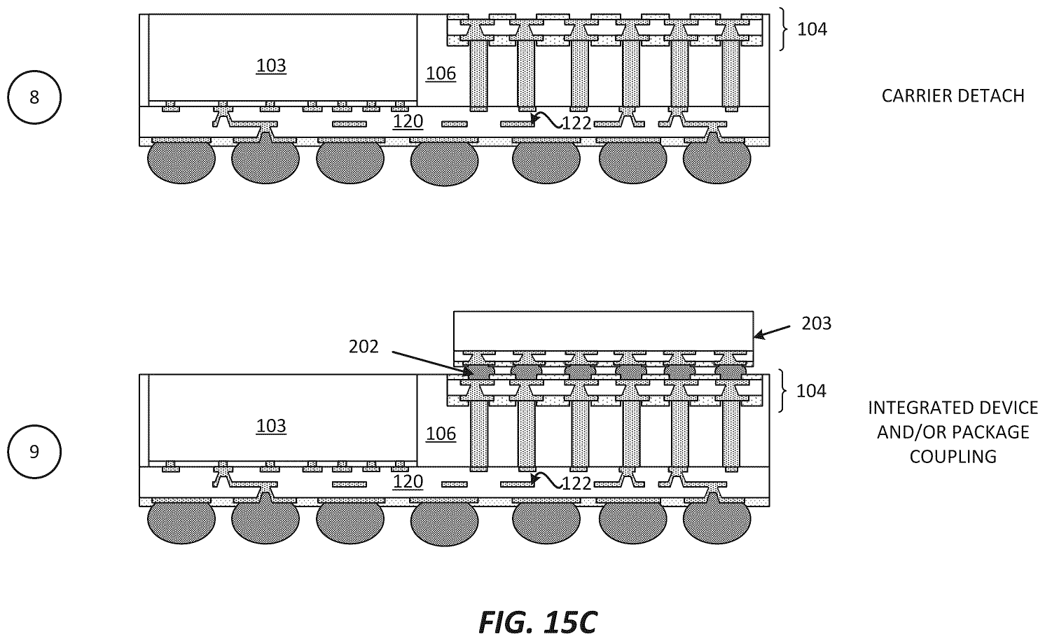

In some implementations, fabricating a package includes several processes. FIGS. 15A-15C illustrate an exemplary sequence for providing or fabricating a package. In some implementations, the sequence of FIGS. 15A-15C may be used to provide or fabricate the package 600. However, the process of FIGS. 15A-15C may be used to fabricate any of the packages described in the disclosure.

It should be noted that the sequence of FIGS. 15A-15C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 15A, illustrates a state after a substrate 104 is provided, placed and/or coupled to a carrier 1000. The carrier 1000 may include glass. An adhesive may be used to place and couple the substrate 104 to the carrier 1000. The substrate 104 may include at least one dielectric layer 140, a plurality of interconnects 142, a solder resist layer 144 and a solder resist layer 146.

Stage 2 illustrates a state after a plurality of post interconnects 608 are formed and coupled to the substrate 104. The plurality of post interconnects 608 may be formed and coupled to the plurality of interconnects 142 of the substrate 104. A lithography process, a plating process, a strip process and/or an etching process may be used to form the plurality of interconnects 142 of the substrate 104. In some implementations, the plurality of post interconnects 608 are part of the substrate 104 when the substrate 104 is placed and coupled to the carrier 1000.

Stage 3 illustrates a state after the integrated device 103 is provided, placed and/or coupled to a carrier 1000. An adhesive may be used to place and couple the integrated device 103 to the carrier 1000. The back side of the integrated device 103 may be coupled to the carrier 1000.

Stage 4 illustrates a state after an encapsulation layer 106 is provided and coupled to the carrier 1000. The encapsulation layer 106 may at least partially encapsulate the integrated device 103, the substrate 104 and the plurality of post interconnects 608. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off.

Stage 5 of FIG. 15B, illustrates a state a planarization process of the encapsulation layer 106. A portion of the encapsulation layer 106 and a portion of the plurality of post interconnects 608 may be removed and/or grinded off.

Stage 6 illustrates a state after a metallization portion 102 is formed and coupled to the integrated device 103, the encapsulation layer 106 and the plurality of post interconnects 608. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 7 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 8 of FIG. 15C, illustrates a state after the carrier 1000 is detached from the encapsulation layer 106, the integrated device 103 and the substrate 104.

Stage 9 illustrates a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 9 may illustrate a package 600 that includes an integrated device and a plurality of post interconnects.

### Exemplary Sequence for Fabricating a Package Comprising Post Interconnects

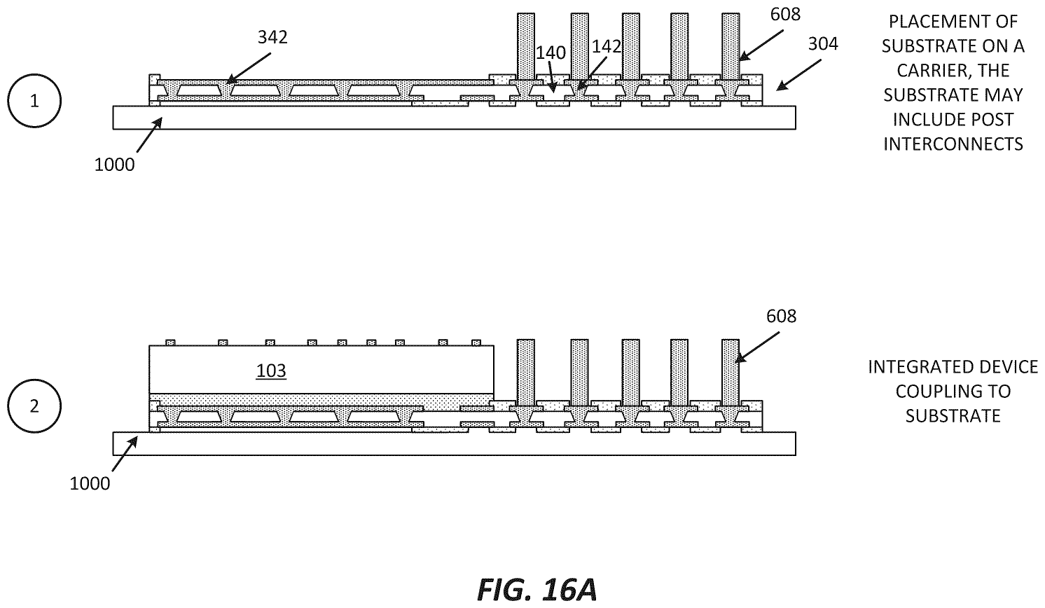

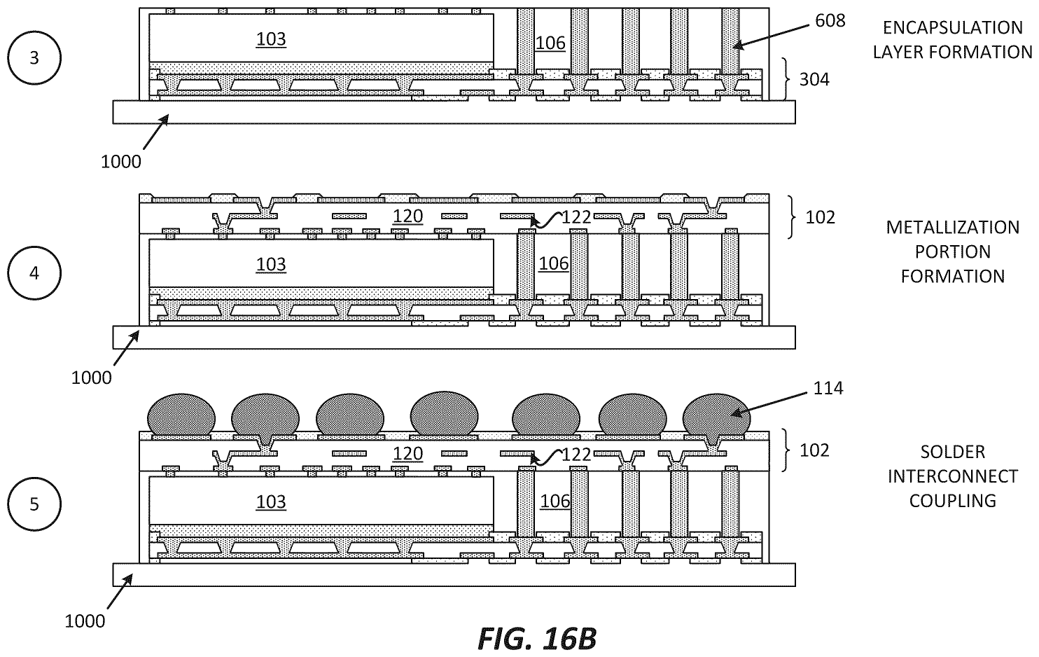

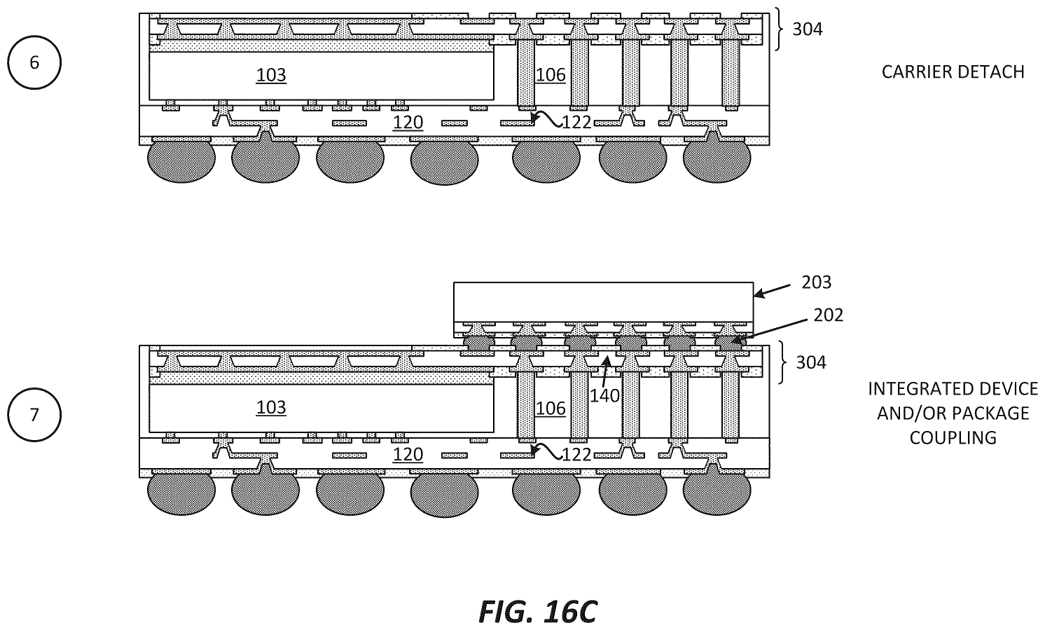

In some implementations, fabricating a package includes several processes. FIGS. 16A-16C illustrate an exemplary sequence for providing or fabricating a package. In some implementations, the sequence of FIGS. 16A-16C may be used to provide or fabricate the package 700. However, the process of FIGS. 16A-16C may be used to fabricate any of the packages described in the disclosure.

It should be noted that the sequence of FIGS. 16A-16C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 16A, illustrates a state after a substrate 304 is provided, placed and/or coupled to a carrier 1000. The carrier 1000 may include glass. An adhesive may be used to place and couple the substrate 304 to the carrier 1000. The substrate 304 may include at least one dielectric layer 140, a plurality of interconnects 142, a plurality of interconnects 342, a solder resist layer 144 and a solder resist layer 146. The plurality of interconnects 342 may be configured to operate as a heat sink. The substrate 304 may also include a plurality of post interconnects 608. In some implementations, the plurality of post interconnects 608 may be formed and coupled to the plurality of interconnects 142 after the substrate 304 is coupled to the carrier 1000.

Stage 2 illustrates a state after an integrated device 103 is coupled to the substrate 304 through a thermal interface material (TIM) 306. A back side of the integrated device 103 may be coupled to the substrate 304 through the thermal interface material (TIM) 306. For example, a back side of the integrated device 103 may be coupled to the plurality of interconnects 342 through the thermal interface material (TIM) 306.

Stage 3, as shown in FIG. 16B, illustrates a state after an encapsulation layer 106 is provided and coupled to the carrier 1000. The encapsulation layer 106 may at least partially encapsulate the integrated device 103, the substrate 304 and the plurality of post interconnects 608. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 4 illustrates a state after a metallization portion 102 is formed and coupled to the integrated device 103, the encapsulation layer 106 and the plurality of post interconnects 608. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 5 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 6 of FIG. 16C, illustrates a state after the carrier 1000 is detached from the encapsulation layer 106, the integrated device 103 and the substrate 304.

Stage 7 illustrates a state after a package 203 is coupled to the substrate 304 through a plurality of solder interconnects 202. A solder reflow process may be used to couple the plurality of solder interconnects 202 to interconnects of the package 203 and the plurality of interconnects 142 of the substrate 304. Stage 7 may illustrate a package 700 that includes an integrated device and a plurality of post interconnects.

### Exemplary Sequence for Fabricating a Package Comprising Post Interconnects

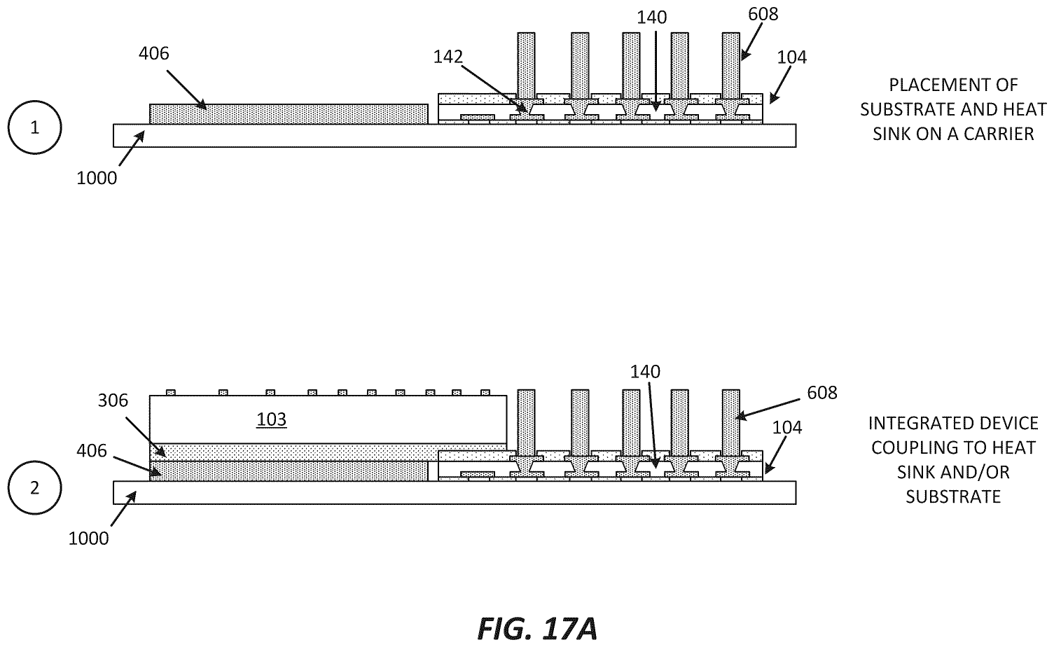

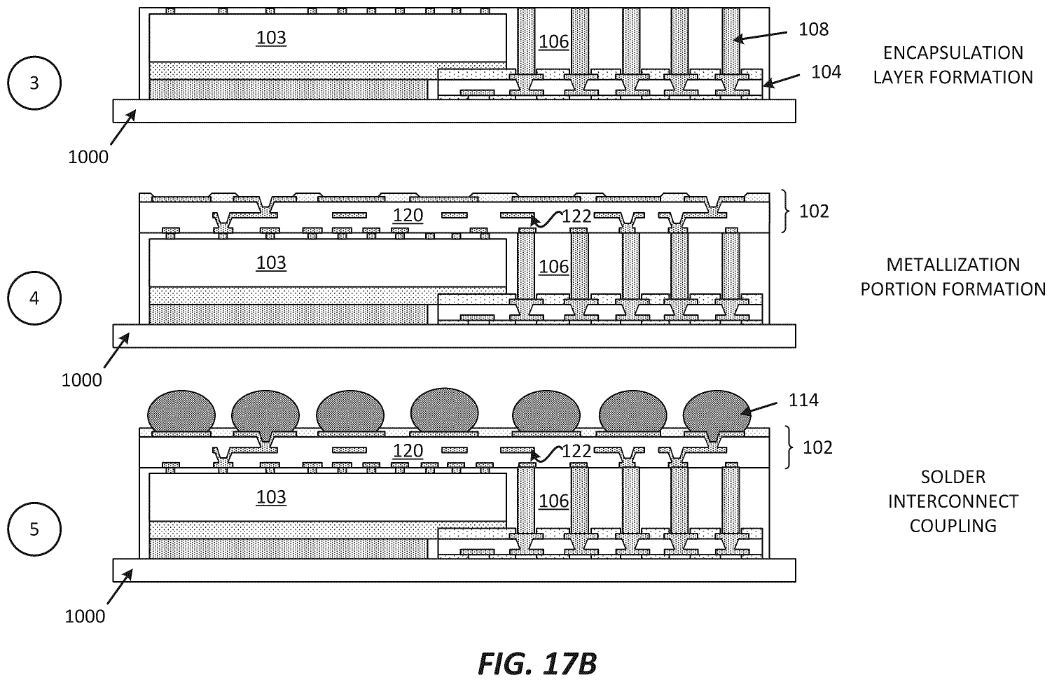

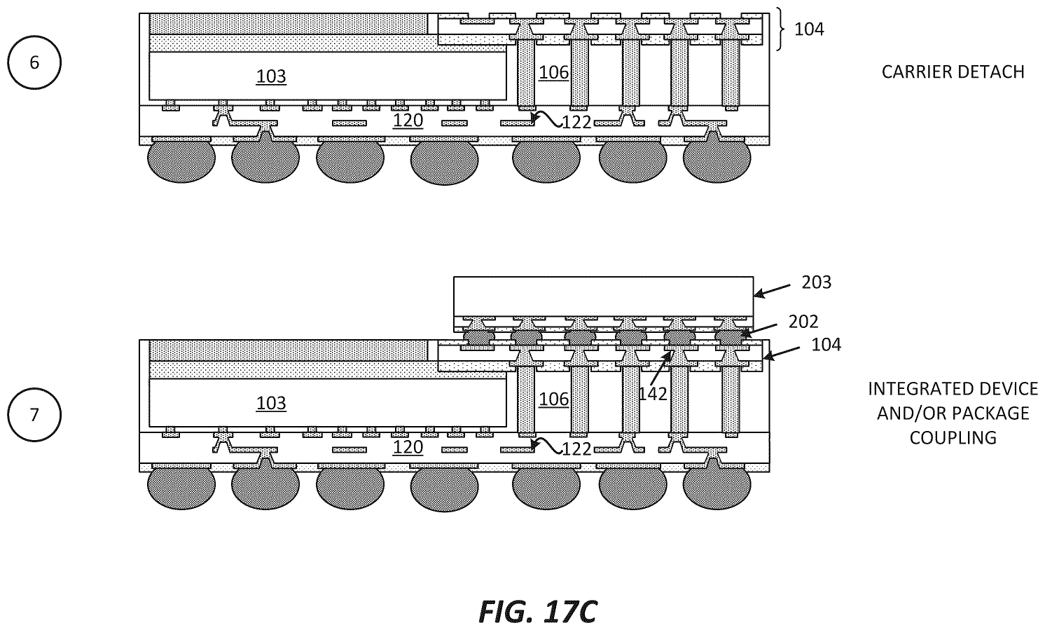

In some implementations, fabricating a package includes several processes. FIGS. 17A-17C illustrate an exemplary sequence for providing or fabricating a package. In some implementations, the sequence of FIGS. 17A-17C may be used to provide or fabricate the package 800. However, the process of FIGS. 17A-17C may be used to fabricate any of the packages described in the disclosure.

It should be noted that the sequence of FIGS. 17A-17C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 17A, illustrates a state after a substrate 104 is provided, placed and/or coupled to a carrier 1000. The carrier 1000 may include glass. An adhesive may be used to place and couple the substrate 104 to the carrier 1000. The substrate 104 may include at least one dielectric layer 140, a plurality of interconnects 142, a solder resist layer 144 and a solder resist layer 146. A heat sink 406 may also be provided, placed and/or coupled to the carrier 1000. An adhesive may be used to place and couple the heat sink 406 to the carrier 1000. The substrate 104 may also include a plurality of post interconnects 608. In some implementations, the plurality of post interconnects 608 may be formed and coupled to the plurality of interconnects 142 after the substrate 104 is coupled to the carrier 1000.

Stage 2 illustrates a state after an integrated device 103 is coupled to the substrate 104 and the heat sink 406 through a thermal interface material (TIM) 306. A back side of the integrated device 103 may be coupled to the substrate 104 and the heat sink 406 through the thermal interface material (TIM) 306.

Stage 3, as shown in FIG. 17B, illustrates a state after an encapsulation layer 106 is provided and coupled to the carrier 1000. The encapsulation layer 106 may at least partially encapsulate the integrated device 103, the substrate 104, the heat sink 406, the thermal interface material (TIM) 306 and the plurality of post interconnects 608. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 4 illustrates a state after a metallization portion 102 is formed and coupled to the integrated device 103, the encapsulation layer 106 and the plurality of post interconnects 608. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 5 illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 6 of FIG. 17C, illustrates a state after the carrier 1000 is detached from the encapsulation layer 106, the integrated device 103 and the substrate 104.

Stage 7 illustrates a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 7 may illustrate a package 800 that includes an integrated device and a plurality of wire bonds.

### Exemplary Sequence for Fabricating a Package Comprising Post Interconnects

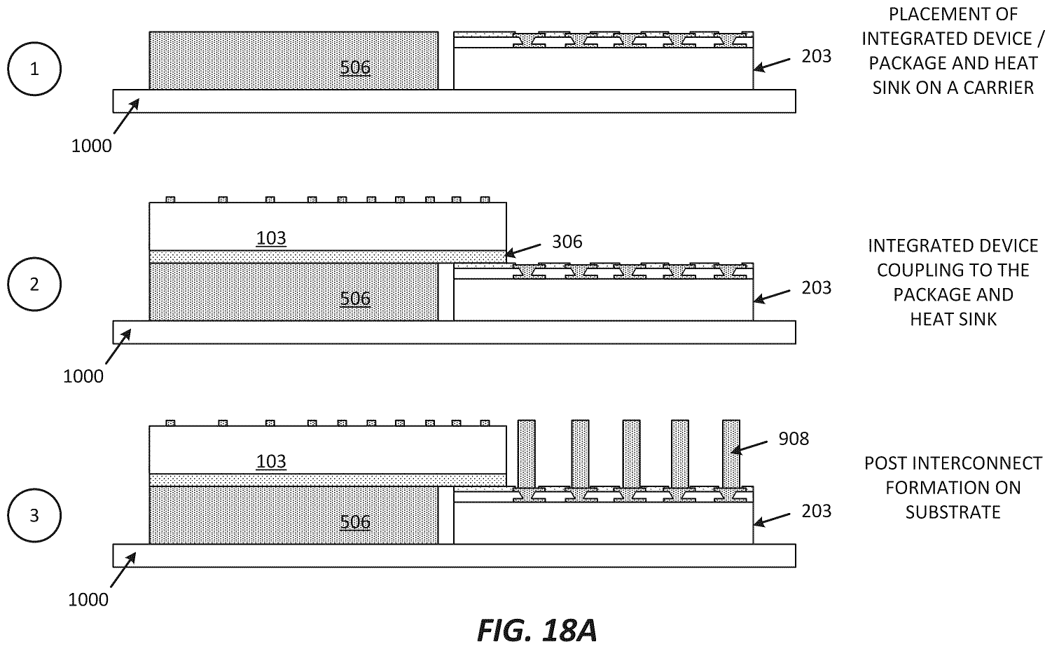

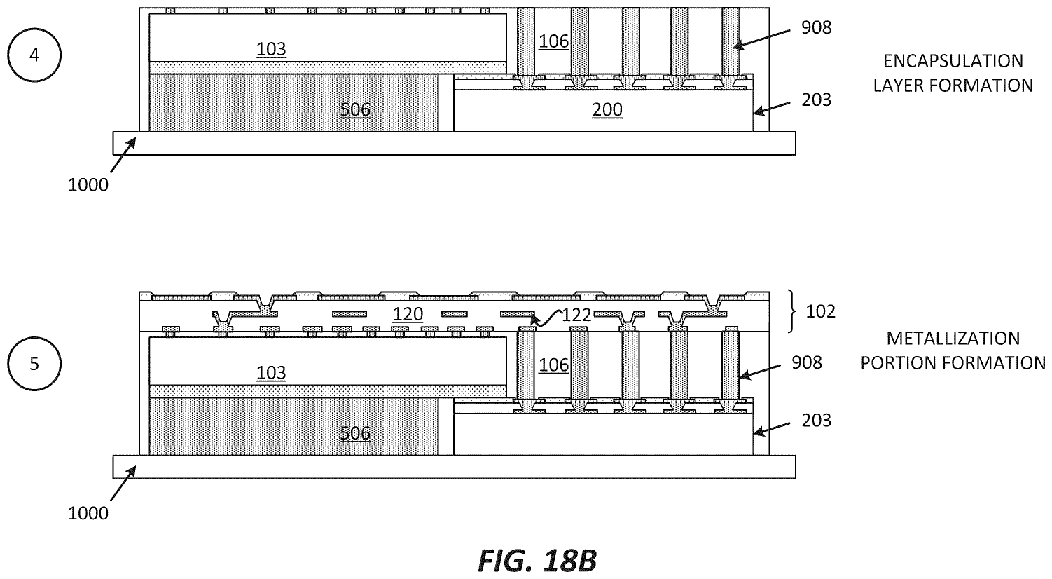

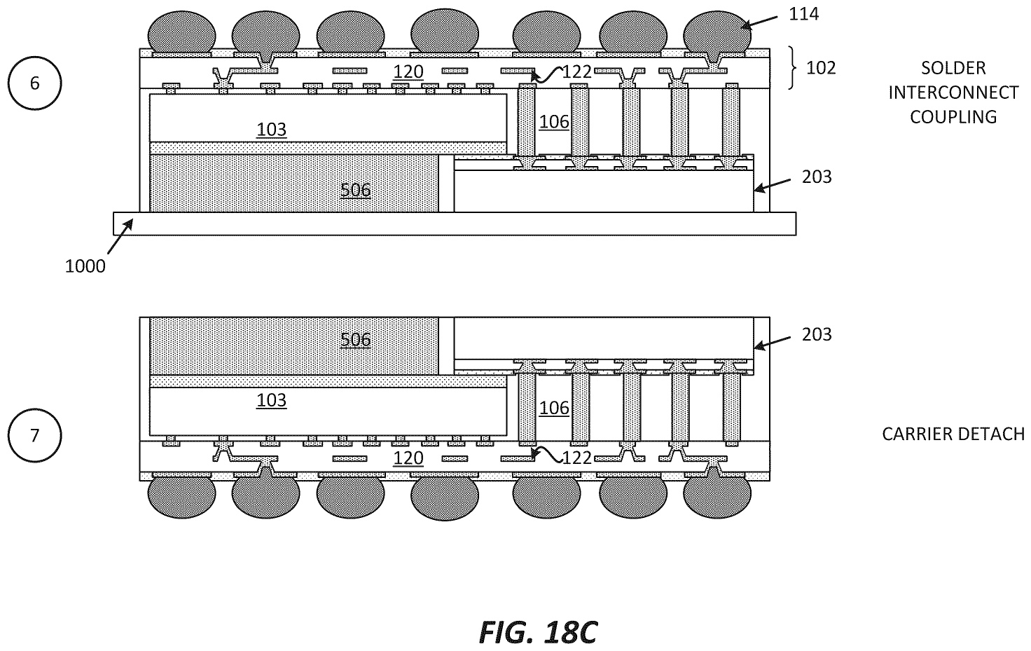

In some implementations, fabricating a package includes several processes. FIGS. 18A-18C illustrate an exemplary sequence for providing or fabricating a package. In some implementations, the sequence of FIGS. 18A-18C may be used to provide or fabricate the package 900. However, the process of FIGS. 18A-18C may be used to fabricate any of the packages described in the disclosure.

It should be noted that the sequence of FIGS. 18A-18C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 18A, illustrates a state after a package 203 is provided, placed and/or coupled to a carrier 1000. The carrier 1000 may include glass. An adhesive may be used to place and couple the package 203 to the carrier 1000. A back side of the package 203 may be coupled to the carrier 1000. A heat sink 506 may also be provided, placed and/or coupled to the carrier 1000. An adhesive may be used to place and couple the heat sink 506 to the carrier 1000.

Stage 2 illustrates a state after an integrated device 103 is coupled to the package 203 and the heat sink 506 through a thermal interface material (TIM) 306. A back side of the integrated device 103 may be coupled to the package 203 and the heat sink 406 through the thermal interface material (TIM) 306. A back side of the integrated device 103 may be coupled to a front side of the package 203 through the thermal interface material (TIM) 306.

Stage 3 illustrates a state after a plurality of post interconnects 908 are formed and coupled to the package 203. The plurality of post interconnects 908 may be coupled to interconnects of the package 203 (e.g., metallization interconnects, substrate interconnects, pad interconnects of the package 203). A lithography process, a plating process, a strip process and/or an etching process may be used to form the plurality of post interconnects 908. In some implementations, the package 203 may already include the plurality of post interconnects 908, when the package 203 is placed and coupled to the carrier 1000 at stage 1. In some implementations, the package 203 may be formed prior to the integrated device 103 being coupled to the package 203.

Stage 4, as shown in FIG. 18B, illustrates a state after an encapsulation layer 106 is provided and coupled to the carrier 1000. The encapsulation layer 106 may at least partially encapsulate the integrated device 103, the package 203, the heat sink 506, the thermal interface material (TIM) 306 and the plurality of post interconnects 908. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

Stage 5 illustrates a state after a metallization portion 102 is formed and coupled to the integrated device 103, the encapsulation layer 106 and the plurality of post interconnects 908. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

Stage 6, as shown in FIG. 18C, illustrates a state after a plurality of solder interconnects 114 are coupled to the metallization portion 102. A solder reflow process may be used to couple the plurality of solder interconnects 114 to the plurality of metallization interconnects 122 of the metallization portion 102.

Stage 7 illustrates a state after the carrier 1000 is detached from the encapsulation layer 106, the integrated device 103 and the package 203. Stage 7 may illustrate the package 900.

### Exemplary Flow Diagram of a Method for Fabricating a Package Comprising Post Interconnects

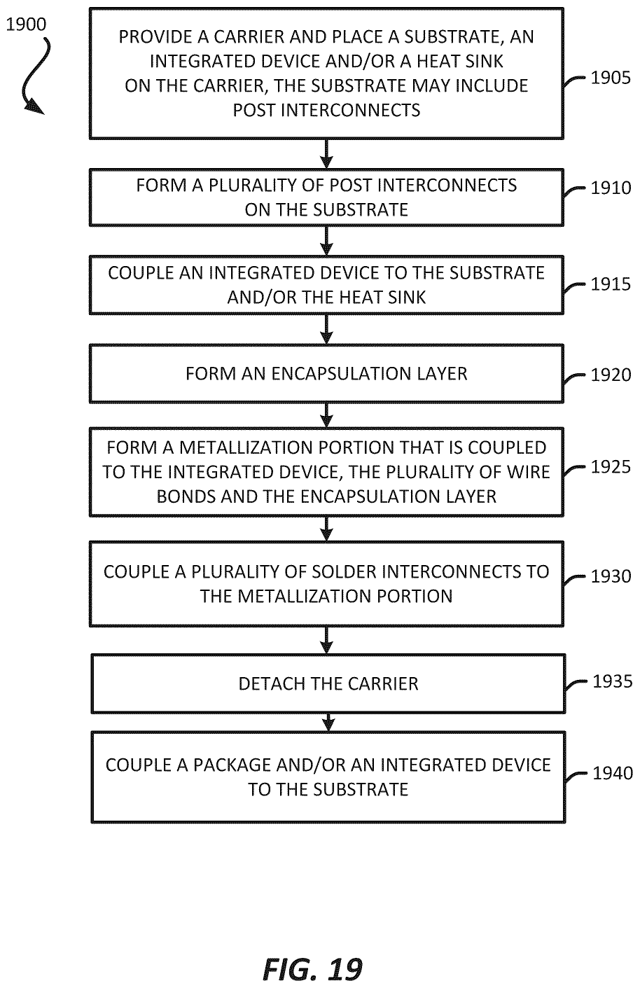

In some implementations, fabricating a package includes several processes. FIG. 19 illustrates an exemplary flow diagram of a method 1900 for providing or fabricating a package. In some implementations, the method 1900 of FIG. 19 may be used to provide or fabricate the package 600, the package 700, and/or the package 800 described in the disclosure. However, the method 1900 may be used to provide or fabricate any of the packages described in the disclosure.

It should be noted that the method 1900 of FIG. 19 may combine one or more processes in order to simplify and/or clarify the method for providing or fabricating a package. In some implementations, the order of the processes may be changed or modified.

The method provides (at 1905) a carrier and couples a substrate, a heat sink and/or an integrated device to the carrier. Stage 1 of FIG. 17A, illustrates and describes an example of a state after a substrate 104 is provided, placed and/or coupled to a carrier 1000. The carrier 1000 may include glass. An adhesive may be used to place and couple the substrate 104 to the carrier 1000. The substrate 104 may include at least one dielectric layer 140, a plurality of interconnects 142, a solder resist layer 144 and a solder resist layer 146. A heat sink 406 may also be provided, placed and/or coupled to the carrier 1000. An adhesive may be used to place and couple the heat sink 406 to the carrier 1000. The substrate 104 may include a plurality of post interconnects 608.

The method may couple (at 1910) an integrated device to the substrate and/or the heat sink. Stage 2 of FIG. 17A, illustrates and describes an example of a state after an integrated device 103 is coupled to the substrate 104 and the heat sink 406 through a thermal interface material (TIM) 306. A back side of the integrated device 103 may be coupled to the substrate 104 and the heat sink 406 through the thermal interface material (TIM) 306.

The method may form (at 1915) a plurality of post interconnects on a substrate. The plurality of post interconnects 608 may be formed and coupled to a substrate 104. The plurality of post interconnects 608 may be formed when the substrate 104 does not already include a plurality of post interconnects.

The method forms (at 1920) an encapsulation layer. Stage 3 of FIG. 17B, illustrates and describes an example of a state after an encapsulation layer 106 is provided and coupled to the carrier 1000. The encapsulation layer 106 may at least partially encapsulate the integrated device 103, the substrate 104, the heat sink 406, the thermal interface material (TIM) 306 and the plurality of post interconnects 608. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded and portions of the encapsulation layer 106 may be removed and/or grinded off. For example, a planarization process of the encapsulation layer 106 may also be performed.

The method forms (at 1925) a metallization portion that is coupled to the integrated device, the substrate and/or the heat sink. Stage 4 of FIG. 17B, illustrates and describes an example of a state after a metallization portion 102 is formed and coupled to the integrated device 103, the encapsulation layer 106 and the plurality of post interconnects 608. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 20A-20B.

The method couples (at 1930) a plurality of solder interconnects to the metallization portion. Stage 5 of FIG. 17B, illustrates and describes an example of a state after a plurality of solder interconnects 114 are coupled to the metallization portion 102. A solder reflow process may be used to couple the plurality of solder interconnects 114 to the plurality of metallization interconnects 122 of the metallization portion 102.

The method detaches (at 1935) the carrier. Stage 6 of FIG. 17C, illustrates and describes an example of a state after the carrier 1000 is detached from the encapsulation layer 106, the integrated device 103 and the substrate 104.

The method couples (at 1940) an integrated device and/or a package to the substrate. Stage 7 of FIG. 17C, illustrates and describes an example of a state after a package 203 is coupled to the substrate 104 through a plurality of solder interconnects 202. A solder reflow process may be used to couple the plurality of solder interconnects 202 to interconnects of the package 203 and the plurality of interconnects 142 of the substrate 104. Stage 7 may illustrate a package 800 that includes an integrated device and a plurality of wire bonds.

### Exemplary Sequence for Fabricating a Metallization Portion

In some implementations, fabricating a substrate includes several processes. FIGS. 20A-20B illustrate an exemplary sequence for providing or fabricating a metallization portion. In some implementations, the sequence of FIGS. 20A-20B may be used to provide or fabricate the metallization portion 102. However, the process of FIGS. 20A-20B may be used to fabricate any of the metallization portions described in the disclosure.

It should be noted that the sequence of FIGS. 20A-20B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 20A, illustrates a state after a carrier 2000 is provided. A seed layer 2001 may be located over the carrier 2000. The carrier 2000 may be replaced with other components and/or materials.

Stage 2 illustrates a state after a plurality of interconnects 2012 are formed. The interconnects 2012 may be located over the seed layer 2001. A lithography process, a plating process, a strip process and/or an etching process may be used to form the plurality of interconnects 2012. The interconnects 2012 may represent at least some of the interconnects from the plurality of metallization interconnects 123.

Stage 3 illustrates a state after a dielectric layer 2010 is formed over the carrier 2000, the seed layer 2001 and the plurality of interconnects 2012. A deposition and/or lamination process may be used to form the dielectric layer 2010. The dielectric layer 2010 may include prepreg and/or polyimide. The dielectric layer 2010 may include a photo-imageable dielectric. However, different implementations may use different materials for the dielectric layer.

Stage 4 illustrates a state after a plurality of cavities 2013 is formed in the dielectric layer 2010. The plurality of cavities 2013 may be formed using an etching process (e.g., photo etching process), a laser process, an exposure process and/or a development process.

Stage 5 illustrates a state after interconnects 2022 are formed in and over the dielectric layer 2010, including in and over the plurality of cavities 2013. For example, a via, pad and/or traces may be formed. A lithography process, a plating process, a strip process and/or an etching process may be used to form the interconnects.

Stage 6, as shown in FIG. 20B, illustrates a state after a dielectric layer 2020 is formed over the dielectric layer 2010 and the plurality of interconnects 2022. A deposition and/or lamination process may be used to form the dielectric layer 2020. The dielectric layer 2020 may include prepreg and/or polyimide. The dielectric layer 2020 may include a photo-imageable dielectric. However, different implementations may use different materials for the dielectric layer.

Stage 7, illustrates a state after a plurality of cavities 2023 is formed in the dielectric layer 2040. The dielectric layer 2040 may represent the dielectric layer 2010 and/or the dielectric layer 2020. The plurality of cavities 2023 may be formed using an etching process (e.g., photo etching process), a laser process, an exposure process and/or a development process.

Stage 8 illustrates a state after interconnects 2032 are formed in and over the dielectric layer 2040, including in and over the plurality of cavities 2023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

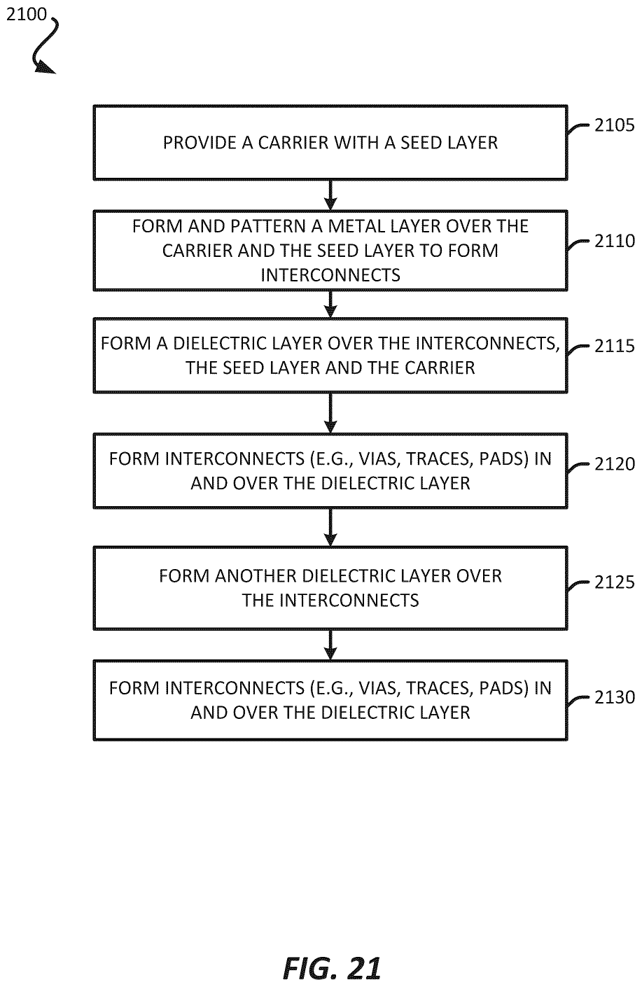

In some implementations, fabricating a substrate includes several processes. FIG. 21 illustrates an exemplary flow diagram of a method 2100 for providing or fabricating a metallization portion. In some implementations, the method 2100 of FIG. 21 may be used to provide or fabricate the metallization portion(s) of the disclosure. For example, the method 2100 of FIG. 21 may be used to fabricate the metallization portion 102.

It should be noted that the method 2100 of FIG. 21 may combine one or more processes in order to simplify and/or clarify the method for providing or fabricating a metallization portion. In some implementations, the order of the processes may be changed or modified.

The method provides (at 2105) a carrier with a seed layer. Stage 1 of FIG. 20A, illustrates and describes an example of a state after a carrier 2000 is provided. A seed layer 2001 may be located over the carrier 2000. The carrier 2000 may be replaced with other components and/or materials.

The method forms and patterns (at 2110) a plurality of interconnects. Stage 2 of FIG. 20A, illustrates and describes an example of a state after a plurality of interconnects 2012 are formed. The interconnects 2012 may be located over the seed layer 2001. A lithography process, a plating process, a strip process and/or an etching process may be used to form the plurality of interconnects 2012. The interconnects 2012 may represent at least some of the interconnects from the plurality of metallization interconnects 123.

The method forms (at 2110) a dielectric layer. Stage 3 of FIG. 20A, illustrates and describes an example of a state after a dielectric layer 2010 is formed over the carrier 2000, the seed layer 2001 and the plurality of interconnects 2012. A deposition and/or lamination process may be used to form the dielectric layer 2010. The dielectric layer 2010 may include prepreg and/or polyimide. The dielectric layer 2010 may include a photo-imageable dielectric. However, different implementations may use different materials for the dielectric layer.

The method forms (at 2120) a plurality of interconnects. Forming a plurality of interconnects may including forming a plurality of cavities in a dielectric layer and a performing a plating process. Stage 4 of FIG. 20A, illustrates and describes an example of a state after a plurality of cavities 2013 is formed in the dielectric layer 2010. The plurality of cavities 2013 may be formed using an etching process (e.g., photo etching process), a laser process, an exposure process and/or a development process.

Stage 5 of FIG. 20A, illustrates and describes an example of a state after interconnects 2022 are formed in and over the dielectric layer 2010, including in and over the plurality of cavities 2013. For example, a via, pad and/or traces may be formed. A lithography process, a plating process, a strip process and/or an etching process may be used to form the interconnects.

The method forms (at 2125) another dielectric layer. Stage 6 of FIG. 20B, illustrates and describes an example of a state after a dielectric layer 2020 is formed over the dielectric layer 2010 and the plurality of interconnects 2022. A deposition and/or lamination process may be used to form the dielectric layer 2020. The dielectric layer 2020 may include prepreg and/or polyimide. The dielectric layer 2020 may include a photo-imageable dielectric. However, different implementations may use different materials for the dielectric layer.

The method forms (at 2130) a plurality of interconnects. Forming a plurality of interconnects may including forming a plurality of cavities in a dielectric layer and a performing a plating process. Stage 7 of FIG. 20B, illustrates and describes an example of a state after a plurality of cavities 2023 is formed in the dielectric layer 2040. The dielectric layer 2040 may represent the dielectric layer 2010 and/or the dielectric layer 2020. The plurality of cavities 2023 may be formed using an etching process (e.g., photo etching process), a laser process, an exposure process and/or a development process.

Stage 8 of FIG. 20B, illustrates and describes an example of a state after interconnects 2032 are formed in and over the dielectric layer 2040, including in and over the plurality of cavities 2023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

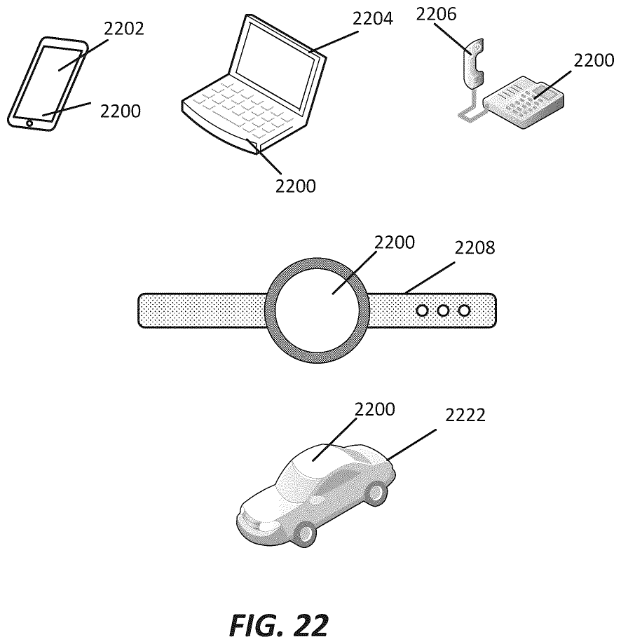

FIG. 22 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 2202, a laptop computer device 2204, a fixed location terminal device 2206, a wearable device 2208, or automotive vehicle 2210 may include a device 2200 as described herein. The device 2200 may be, for example, any of the devices and/or integrated circuit (IC) packages described herein. The devices 2202, 2204, 2206 and 2208 and the vehicle 2210 illustrated in FIG. 22 are merely exemplary. Other electronic devices may also feature the device 2200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-9, 10A-10C, 11A-11C, 12A-12C, 13A-13C, 14, 15A-15C, 16A-16C, 17A-17C, 18A-18C, 19, 20A-20B, and 21-22 may be rearranged and/or combined into a single component, process, feature or function or embodied in several components, processes, or functions. Additional elements, components, processes, and/or functions may also be added without departing from the disclosure. It should also be noted FIGS. 1-9, 10A-10C, 11A-11C, 12A-12C, 13A-13C, 14, 15A-15C, 16A-16C, 17A-17C, 18A-18C, 19, 20A-20B, and 21-22 and its corresponding description in the present disclosure is not limited to dies and/or ICs. In some implementations, FIGS. 1-9, 10A-10C, 11A-11C, 12A-12C, 13A-13C, 14, 15A-15C, 16A-16C, 17A-17C, 18A-18C, 19, 20A-20B, and 21-22 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a metallization portion; an integrated device coupled to the metallization portion; a substrate; a plurality of wire bonds coupled to the substrate and the metallization portion; and an encapsulation layer coupled to the metallization portion, wherein the encapsulation layer at least partially encapsulates the integrated device, the plurality of wire bonds and the substrate.

Aspect 2: The package of aspect 1, wherein the substrate includes an interposer.

Aspect 3: The package of aspects 1 through 2, wherein the substrate comprises at least one substrate dielectric layer and a plurality of interconnects, and wherein the metallization portion comprises at least one dielectric layer and a plurality of metallization interconnects.

Aspect 4: The package of aspect 3, wherein the plurality of wire bonds are coupled to the plurality of interconnects and the plurality of metallization interconnects.

Aspect 5: The package of aspects 1 through 4, further comprising another integrated device or another package, coupled to the substrate through a plurality of solder interconnects.

Aspect 6: The package of aspect 1 through 5, wherein the integrated device is coupled to the substrate through a thermal interface material (TIM) and/or an adhesive.

Aspect 7: The package of aspect 6, wherein the substrate comprises a plurality of heat sink interconnects configured as a heat sink.

Aspect 8: The package of aspect 1 through 6, further comprising a heat sink, wherein the integrated device is coupled to the heat sink through a thermal interface material (TIM) and/or an adhesive.

Aspect 9: A package comprising a metallization portion; a first integrated device coupled to the metallization portion; a second integrated device; a heat sink coupled to the first integrated device through a thermal interface material (TIM) and/or an adhesive; a plurality of package interconnects coupled to the second integrated device and the metallization portion; and an encapsulation layer coupled to the metallization portion, wherein the encapsulation layer at least partially encapsulates the first integrated device, the second integrated device, the plurality of package interconnects and the heat sink.

Aspect 10: The package of aspect 9, wherein the plurality of package interconnects comprise a plurality of wire bonds or a plurality of post interconnects.

Aspect 11: A package comprising a metallization portion; an integrated device coupled to the metallization portion; a substrate; a plurality of post interconnects coupled to the substrate and the metallization portion; and an encapsulation layer coupled to the metallization portion, wherein the encapsulation layer at least partially encapsulates the integrated device, the plurality of post interconnects and the substrate.

Aspect 12: The package of aspect 11, wherein the substrate includes an interposer.

Aspect 13: The package of aspects 11 through 12, wherein the substrate comprises at least one substrate dielectric layer and a plurality of interconnects, and wherein the metallization portion comprises at least one dielectric layer and a plurality of metallization interconnects.

Aspect 14: The package of aspect 13, wherein the plurality of post interconnects are coupled to the plurality of interconnects and the plurality of metallization interconnects.

Aspect 15: The package of aspects 11 through 14, further comprising another integrated device or another package coupled to the substrate through a plurality of solder interconnects.

Aspect 16: The package of aspects 11 through 15, wherein the integrated device is coupled to the substrate through a thermal interface material (TIM) and/or an adhesive.

Aspect 17: The package of aspect 16, wherein the substrate comprises a plurality of heat sink interconnects configured as a heat sink.

Aspect 18: The package of aspects 11 through 16, further comprising a heat sink, wherein the integrated device is coupled to the heat sink through a thermal interface material (TIM) and/or an adhesive.

Aspect 19: The package of aspects 11 through 18, wherein the plurality of post interconnects comprise a post interconnect with a height and a width, and wherein the height of the post interconnect is at least 2 times greater than the width of the post interconnect.

Aspect 20: The package of aspects 11 through 19, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a metallization portion;
an integrated device coupled to the metallization portion;
a substrate;
a plurality of wire bonds coupled to the substrate and the metallization portion; and
an encapsulation layer coupled to the metallization portion, wherein the encapsulation layer at least partially encapsulates the integrated device, the plurality of wire bonds and the substrate.

2. The package of claim 1, wherein the substrate includes an interposer.

3. The package of claim 1,
wherein the substrate comprises at least one substrate dielectric layer and a plurality of interconnects, and
wherein the metallization portion comprises at least one dielectric layer and a plurality of metallization interconnects.

4. The package of claim 3, wherein the plurality of wire bonds are coupled to the plurality of interconnects and the plurality of metallization interconnects.

5. The package of claim 1, further comprising another integrated device or another package, coupled to the substrate through a plurality of solder interconnects.

6. The package of claim 1, wherein the integrated device is coupled to the substrate through a thermal interface material (TIM) and/or an adhesive.

7. The package of claim 6, wherein the substrate comprises a plurality of heat sink interconnects configured as a heat sink.

8. The package of claim 1, further comprising a heat sink, wherein the integrated device is coupled to the heat sink through a thermal interface material (TIM) and/or an adhesive.

9. A package comprising:
a metallization portion;
a first integrated device coupled to the metallization portion;
a second integrated device;
a heat sink coupled to the first integrated device through a thermal interface material (TIM) and/or an adhesive;
a plurality of package interconnects coupled to the second integrated device and the metallization portion; and
an encapsulation layer coupled to the metallization portion, wherein the encapsulation layer at least partially encapsulates the first integrated device, the second integrated device, the plurality of package interconnects and the heat sink.

10. The package of claim 9, wherein the plurality of package interconnects comprise a plurality of wire bonds or a plurality of post interconnects.

11. A package comprising:
a metallization portion;
an integrated device coupled to the metallization portion;
a substrate;
a plurality of post interconnects coupled to the substrate and the metallization portion; and
an encapsulation layer coupled to the metallization portion, wherein the encapsulation layer at least partially encapsulates the integrated device, the plurality of post interconnects and the substrate.

12. The package of claim 11, wherein the substrate includes an interposer.

13. The package of claim 11,
wherein the substrate comprises at least one substrate dielectric layer and a plurality of interconnects, and
wherein the metallization portion comprises at least one dielectric layer and a plurality of metallization interconnects.

14. The package of claim 13, wherein the plurality of post interconnects are coupled to the plurality of interconnects and the plurality of metallization interconnects.

15. The package of claim 11, further comprising another integrated device or another package coupled to the substrate through a plurality of solder interconnects.

16. The package of claim 11, wherein the integrated device is coupled to the substrate through a thermal interface material (TIM) and/or an adhesive.

17. The package of claim 16, wherein the substrate comprises a plurality of heat sink interconnects configured as a heat sink.

18. The package of claim 11, further comprising a heat sink, wherein the integrated device is coupled to the heat sink through a thermal interface material (TIM) and/or an adhesive.

19. The package of claim 11,
wherein the plurality of post interconnects comprise a post interconnect with a height and a width, and
wherein the height of the post interconnect is at least 2 times greater than the width of the post interconnect.

20. The package of claim 11, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
